(19) United States
(12) Patent Application Publication
(10) Pub. No.: US 2024/0290872 A1
(43) Pub. Date: Aug. 29, 2024

(54) ELECTRICAL CONTROL OF A QUANTUM PROCESSING ELEMENT

(71) Applicant: Diraq Pty Ltd, Elizabeth Bay, New South Wales (AU)

(72) Inventors: Ross Cho Chun LEON, Elizabeth Bay (AU); André Luiz SARAIVA DE OLIVEIRA, Elizabeth Bay (AU); Chih-Hwan Henry YANG, Elizabeth Bay (AU); Andrew Steven DZURAK, Elizabeth Bay (AU); Tuomo TANTTU, Elizabeth Bay (AU); Wee Han LIM, Elizabeth Bay (AU); Arne LAUCHT, Elizabeth Bay (AU)

(21) Appl. No.: 18/573,329

(22) PCT Filed: Jun. 24, 2022
(86) PCT No.: PCT/AU2022/050649

§ 371 Date: Dec. 21, 2023

(30) Foreign Application Priority Data
Jun. 25, 2021 (AU) 2021901923

(51) Int. Cl. H01L 29/66; G06N 10/40; H01L 29/76

(52) U.S. Cl. CPC H01L 29/66977; G06N 10/40; H01L 29/66984; H01L 29/7613

(57) ABSTRACT

A method of controlling a quantum processing element, the quantum processing element comprising: a semiconductor substrate; a barrier material formed above the semiconductor substrate such that an interface forms between the semiconductor substrate and the barrier material; an arrangement of gate electrodes; an external magnet; and electronic controllers, where the method comprises: generating an electrostatic confinement potential by applying voltages to the arrangement of gate electrodes for binding a controllable number of electrons or holes, forming a first quantum dot; applying a constant magnetic field to the quantum processing element using the external magnet, the magnetic field separating energy levels of spin states associated with an unpaired electron or hole of the controllable number of electrons or holes in the first quantum dot; and changing the voltages of the arrangement of gate electrodes using the electronic controllers to change a shape of a confinement potential of the unpaired electron or hole.

### CROSS REFERENCE TO RELATED APPLICATIONS

The present application is a National Stage entry of International Application No. PCT/AU2022/050649, filed on Jun. 24, 2022, which claims priority to the Australian Application Number 2021901923, filed on Jun. 25, 2021, both of which are incorporated by reference in their entireties.

### TECHNICAL FIELD

Aspects of the present disclosure are related to quantum processing systems and more particularly to silicon-based processing systems.

### BACKGROUND

The exponential progress of microelectronics in the last half century has been based on silicon technology, and despite research on many new materials, silicon has remained the core technological platform for classical computation. Over the past few decades, it has become increasingly evident that silicon can be an excellent host material for an entirely new generation of devices-quantum computing devices, which operate based on the quantum mechanical properties of charges and spins. Silicon is an ideal environment for spins in solid state devices, due to its weak spin-orbit coupling and the abundance of silicon isotopes with zero nuclear spin. The vision of combining quantum spin control with existing fabrication technology currently used in classical computers has encouraged extensive work in silicon-based quantum computing devices.

Large-scale quantum computers have the potential to provide fast solutions to certain classes of computationally difficult problems, with exponentially greater efficiency than a classical computer. In order to realise such a large-scale quantum computer, several challenges in the design and implementation of the quantum architecture to control and program quantum hardware must be overcome.

### SUMMARY

According to a first aspect of the present disclosure there is provided a method of controlling a quantum processing element. The quantum processing element comprising: a semiconductor substrate, a barrier material formed above the semiconductor substrate such that an interface forms between the semiconductor substrate and the barrier material, an arrangement of gate electrodes, an external magnet, and electronic controllers. The method comprises: generating an electrostatic confinement potential by applying voltages to the arrangement of gate electrodes for binding a controllable number of electrons or holes, forming a first quantum dot: applying a constant magnetic field to the quantum processing element using the external magnet, the magnetic field separating energy levels of spin states associated with an unpaired electron or hole of the controllable number of electrons or holes in the first quantum dot; and changing the voltages of the arrangement of gate electrodes using the electronic controllers to change a shape of a confinement potential of the unpaired electron or hole.

According to a second aspect of the present disclosure there is provided a quantum processing element comprising: a semiconductor substrate: a barrier material formed above the semiconductor substrate such that an interface forms between the semiconductor substrate and the barrier material: an arrangement of gate electrodes configured to generate a confining electrostatic potential for binding a controllable number of electrons or holes forming a first quantum dot: an external magnet configured to apply a constant magnetic field to the first quantum dot to separate energy levels of spin states associated with an unpaired electron or hole of the controllable number of electrons or holes in the first quantum dot; and electronic controllers configured to change voltages applied to the arrangement of gate electrodes to change a shape of a confinement potential of the unpaired electron or hole.

In some embodiments, the voltages applied to the arrangement of gate electrodes are modified to change the shape of the confinement potential, which alters an excitation spectrum of the first quantum dot to enable fast control of the spin states of the unpaired electron or hole.

In some embodiments, an additional alternating voltage is applied to the arrangement of gate electrodes in order to electrically drive transitions between spin states of the unpaired electron or hole.

Further, in some embodiments, the voltages applied to the arrangement of gate electrodes are modified to change a shape of the first quantum dot wavefunction, which alters an excitation spectrum of the first quantum dot to enable fast relaxation between the spin states of the unpaired electron or hole.

In some other embodiments, the quantum processing element further comprises a second quantum dot having a controllable number of electrons or holes. In such embodiments, the unpaired electron or hole from the first quantum dot can be temporarily transferred to the second quantum containing an unpaired electron or hole and the voltages applied to the arrangement of gate electrodes can be adjusted to tune a shape of the second quantum dot wavefunction in order to control an exchange energy between the two electrons or holes.

Further, in such embodiments, the voltages applied to the arrangement of gate electrodes are modified to change a shape of the first quantum dot wavefunction, resulting in a change of the wavefunction of the unpaired electron or hole dependent on the spin state of the electron or hole.

In some other embodiments, the quantum processing element includes other quantum dots and the change in the shape of the first quantum dot wavefunction causes an electrostatic repulsion to the other quantum dots resulting in a spin-dependent frequency shift of the unpaired electron or hole in a second quantum dot.

In some such embodiments, the quantum processing element may further include a resonator positioned between the first quantum dot and one of the other quantum dots and an electric field created by the spin-dependent change in wavefunction of the unpaired electron or hole in the first quantum dot couples to a resonator, creating or absorbing a photon.

In yet other embodiments, the quantum processing element is coupled to a second quantum processing element via a resonator, the second quantum processing element comprising a second quantum dot having a controllable number of electrons or holes and an unpaired electron or hole, and wherein an electric field created by the spin state dependent change in the wavefunction of the unpaired electron or hole couples to the resonator, creating or absorbing a photon. Further still, the voltages applied to the arrangement of gate electrodes are modified to change the shape of the first quantum dot wavefunction and the second quantum dot wavefunction coupled to the resonator and the photon created by the spin-dependent change in the wavefunction of the unpaired electron or hole of the first quantum dot is absorbed by the unpaired electron or hole of the second quantum dot, changing its spin state.

As used herein, except where the context requires otherwise, the term “comprise” and variations of the term, such as “comprising”, “comprises” and “comprised”, are not intended to exclude further additives, components, integers or steps.

Further aspects of the present invention and further embodiments of the aspects described in the preceding paragraphs will become apparent from the following description, given by way of example and with reference to the accompanying drawings.

### BRIEF DESCRIPTION OF DRAWINGS

Features and advantages of the present invention will become apparent from the following description of embodiments thereof, by way of example only, with reference to the accompanying drawings, in which:

FIGS. 1A and 1B show a schematic side cross-sectional view of two example quantum dot devices.

FIG. 1C shows a schematic top view of an example quantum processing unit according to some of the embodiments in the present disclosure.

FIG. 2 is a qualitative illustration of a multi-electron quantum dot with 5 electrons.

FIG. 3 shows an example of the dependency of the speed of EDSR induced spin rotations on the shape of the quantum dot. FIG. 3A shows a set up for slow EDSR and FIG. 3B shows a set up for fast EDSR.

FIG. 4A shows an example energy diagram of the lowest four eigenstates of an electron in a quantum dot as a function of a gate voltage.

FIG. 4B shows schematics of the confinement potential and wavefunction for quantum dots in three regimes: two regimes in which the electron is considered to be idle (left and middle columns), and one in which the spin-dependent electric polarisation affects the qubit (right column).

FIG. 5 is a flowchart illustrating a method for controlling spin rotations of a multi-electron quantum dot.

FIG. 6 shows excited state energy of a quantum dot as a function of bias voltage on an exchange gate for a three-electron quantum dot.

FIG. 7A shows measured Rabi frequencies as a function of detuning and gate bias for a three-electron quantum dot.

FIG. 7B shows the trace probability of measuring a singlet in a double quantum dot spin blockade experiment, where one of the dots is the three-electron quantum dot of FIG. 7A, as a function of (electric spin resonance) ESR burst time.

FIG. 8A shows the probability of measuring a singlet in a double quantum dot spin blockade experiment as a function of the voltage bias applied to one of the gates and the frequency of a microwave signal applied to the antenna.

FIG. 8B shows the probability of measuring a singlet in a double quantum dot spin blockade experiment as a function of the voltage bias applied to one of the gates and the duration of the microwave burst.

FIGS. 8C-8E shows the probability of measuring a singlet in a double quantum dot spin blockade experiment as a function of microwave burst time and microwave frequency for different gate voltage biases corresponding to different Rabi oscillation frequencies, 1.5 MHZ, 8.5 MHz and 17 MHz respectively.

FIG. 9A shows a schematic representation of the quantum device energy band diagram.

FIGS. 9B-9C show schematics of the pulse sequences for T₁ relaxation and Rabi control calibration experiment respectively.

FIGS. 9D-9F show the Stark shift of the spin resonance, spin relaxation time and Rabi frequency as a function of gate voltage for a multiple electron quantum dot with 1, 5 and 13 electrons, respectively.

FIGS. 10A-10H show an approach to improved EDSR using the quantum systems and methods of the described embodiments.

FIG. 11 shows a schematic representation of a system of multiple qubits in which all but two qubits are configured to be protected from electric fields, and the two that are configured to be in the spin-dependent electrically polarizable state interact with each other via intermediate-distance dipolar coupling.

FIG. 12 is a block diagram of two quantum dots connected via a microwave resonator.

FIG. 13 is a flowchart illustrating an example method for performing a two-qubit operation according to some aspects of the present disclosure.

FIG. 14A shows a schematic representation of a two-qubit multi-electron quantum dot system.

FIG. 14B shows a schematic representation of the two-qubit system of FIG. 1B with spin shuttling.

### DETAILED DESCRIPTION

### Overview

One type of quantum computing system is based on spin states of individual qubits where the qubits are electron and/or nuclear spins in a semiconductor quantum chip. These electron and/or nuclear spins are confined in gate-defined quantum dots and are referred to as quantum bits or qubits.

Qubit architectures based on electron spins in gate-defined quantum dots benefit from a high level of controllability, where single and multi-qubit coherent operations are realised solely with electrical and/or magnetic manipulation of qubits. In particular, the direct compatibility of such qubit architectures with silicon microelectronics fabrication provides unique opportunities for scaling up to large scale quantum computers.

A building block for any large-scale quantum computer is a quantum gate—i.e., a basic quantum operation acting on one or two qubits. Examples of quantum gates include identity gates, Pauli gates, controlled gates, phase shift gates, SWAP gates, Toffoli gates, etc. Manipulating spin-based qubits in semiconductors, in particular performing fast operations on the spin states of qubits, is an important avenue for constructing a quantum gate. In particular, fast, individually addressable qubit operations (such as unitary transformations, quantum measurements, and initialization) are essential for scalable architectures.

To date there are two main means for manipulating/controlling the spin state of a qubit: magnetic control and electrical control. In magnetic control, either an on-chip generated or off-chip externally generated (or global) magnetic field is applied to a quantum chip to drive/control the qubits. In particular, qubit control can be realised by introducing an alternating magnetic field in a direction perpendicular to an applied DC magnetic field. This is generally done by applying an AC current to on-chip antenna electrodes close to the qubits. The AC current generates an alternating magnetic field. When the frequency of this field matches the resonance frequency of the qubit, the spin qubit begins to rotate as a function of time. These oscillations are called Rabi oscillations and they form the basis of single qubit rotations and control.

Although magnetic control allows for high-fidelity single and two-qubit gates in silicon-based qubits, the technical complexity of generating local oscillating magnetic fields on the nanometre scale (the scale at which quantum dots are often fabricated) remains a significant hurdle for the future scalability of magnetic control. Further, the local oscillating currents often generate heat in the quantum computing chip, which is incompatible with the cryogenic environment necessary for qubit coherence. In the case in which the magnetic field is generated by an on-chip antenna, the antenna takes up precious real estate on the quantum computing chip. These difficulties provide motivation to manipulate spins electrically.

One method for controlling spins electrically is by using electric dipole spin resonance (EDSR). EDSR is generally achieved by coupling the spin qubit to its charge degree-of-freedom, which can be induced by a spin-orbit coupling (SOC). SOC is generally present in atoms and solids-due to a relativistic effect, electrons moving in an electric field experience in their reference frame an effective magnetic field. In the case of silicon, however, SOC is intrinsically weak. To increase the strength of SOC, a number of different mechanisms can be used such as the use of large spin-orbit coupling materials or a magnetic field gradient from a micro-magnet.

Although on-chip micro-magnets help strengthen the SOC, these on-chip micro-magnets take up valuable real estate on the quantum processing chip. Further, fabricating such small micro-magnets on quantum processing chips in close proximity to corresponding qubits is an engineering challenge. Some previously known techniques have attempted to electrically drive and/or control qubits without the need of micro-magnets, leveraging only the natural SOC, however, in these techniques, the rate of Rabi oscillations was too low compared with the decoherence time (i.e., time taken to lose quantum coherence) to provide high-fidelity control.

Aspects of the present disclosure provide a new technique for controlling qubits via electric manipulation. In particular, aspects of the present disclosure provide a quantum computing device that includes one or more quantum dots, each containing a controllable number of electrons, and techniques that facilitate controlled spin rotations of an electron within the quantum dot through manipulation of a wavefunction of the quantum dot. In some examples, the quantum dot wavefunction shape may be tuned through manipulation of an electrostatic potential (also referred to as confinement potential) that confines the quantum dot. Other types of modification of the wavefunction can also be leveraged to lead to the same effect.

The manipulation of the wavefunction in the present disclosure is achieved by controlling the quantised energy levels of the electron within the quantum dot. Advantageous energy configurations can be achieved via this manipulation for quantum dots with three or more electrons. However, the effect can also be achieved by manipulation of the wavefunction of a single electron.

By manipulating the wavefunction of the quantum dot, aspects of the present disclosure can perform qubit operations 10-100 times faster than traditional qubit control/operation techniques, thereby improving qubit fidelity significantly. Further, in some examples of the present disclosure, using the presently disclosed techniques, qubits can be electrically manipulated without using on-chip micro-magnets.

These and other advantages of the presently disclosed qubit device and control/operation techniques will be described in detail in the following sections.

### Example Qubit Device

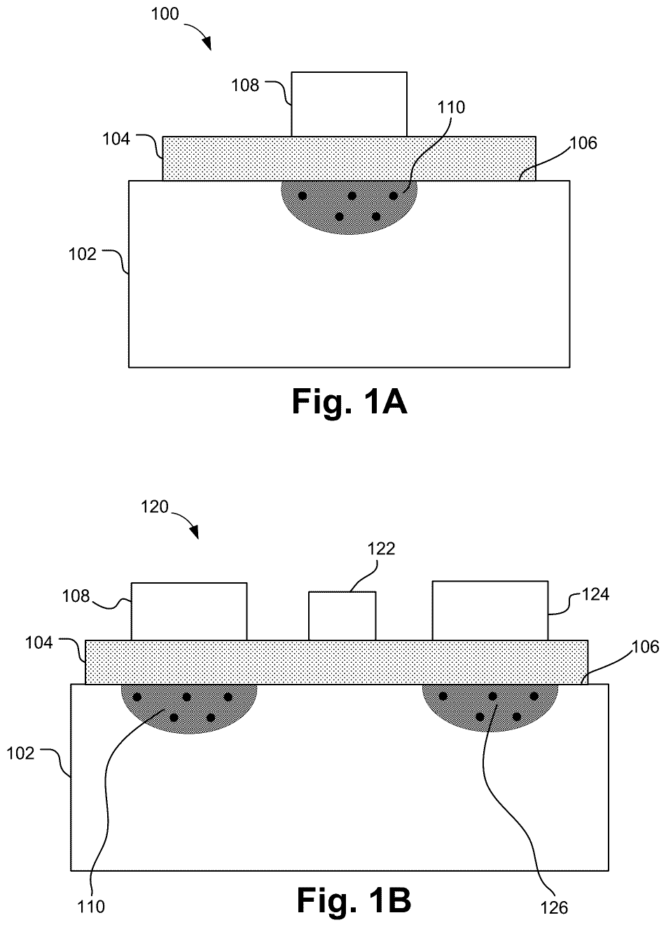

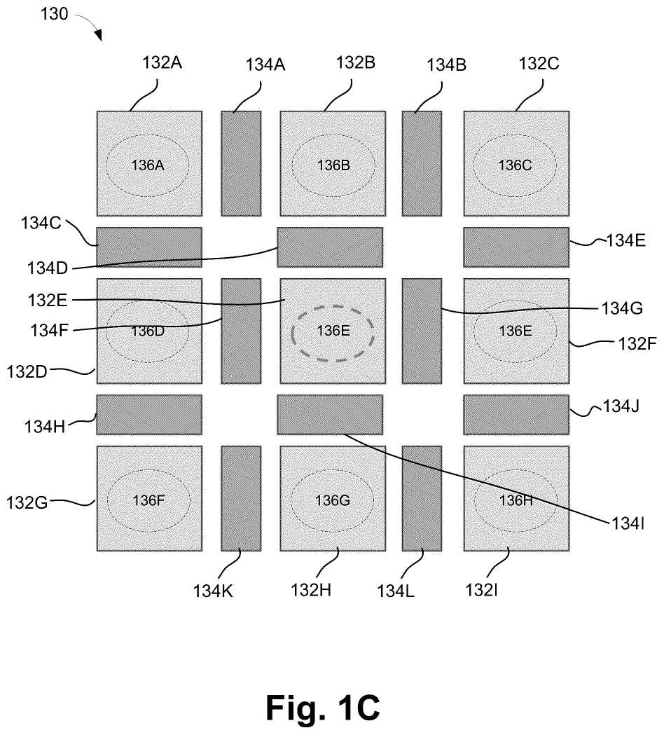

FIG. 1A illustrates an example quantum processing element 100 according to aspects of the present disclosure. In this example, the quantum processing element 100 includes a multi-electron quantum dot 110—i.e., a quantum dot that includes multiple electrons.

The quantum processing element 100 includes a semiconductor substrate 102 topped by a dielectric barrier material 104. In this example, the semiconductor substrate 102 is isotopically enriched ²⁸silicon (Si-28) (which may be an epitaxial layer grown on a conventional silicon substrate) and the dielectric is silicon dioxide (SiO₂). The semiconductor substrate 102 and dielectric 104 form an interface 106, which in this example is a Si/SiO₂ interface. A gate electrode 108 is positioned on the dielectric 104 and is controllable to form a quantum dot 110 at the interface 106. In particular, sufficiently positive voltages applied to gate electrode 108 cause electrons to be confined and form a quantum dot 110.

The dielectric barrier material 104 will typically comprise a material that insulates the movement of electrons or holes. Examples include oxides, such as silicon dioxide, or alloys of silicon and other elements (silicon-germanium or others), or any other material that creates an energy barrier to the penetration of the electron or the hole.

In some examples, the quantum dot 110 may include N electrons where N is an odd integer greater than or equal to one. A qubit may be encoded in the spin of one of the N electrons as described in detail below. The gate electrode 108 may be used to 1) introduce electrons in the quantum dot (from a reservoir, not shown), 2) directly control the spin of the electron using an AC electric field, and 3) alter the wavefunction of electrons in quantum dot 110. In some examples, other dedicated electrodes may be provided to perform one or more of the above functions. For instance, one gate electrode may be provided to alter the wavefunction in the quantum dot 110 whereas another gate electrode may be utilised to control the electron spin of an electron of the quantum dot 110. The gate electrodes provided as part of the quantum processing element 100 form an arrangement of gate electrodes.

FIG. 1B illustrates another example of a quantum processing element 120 according to aspects of the present disclosure, which includes two multi-electron quantum dots 110, 126. Similar to the quantum processing element 100 of FIG. 1A, the quantum processing element 120 includes a semiconductor substrate 102 topped by a dielectric 104. In this example as well, the semiconductor substrate 102 is isotopically enriched silicon Si-28 and the dielectric 104 is SiO₂. The semiconductor substrate 102 and dielectric 104 form an interface 106, which in this example is also a Si/SiO₂ interface 106.

Further, in this example, the quantum processing element 120 includes three gate electrodes—108, 122 and 124, which together form an arrangement of gate electrodes. Gate electrode 108 is positioned on the dielectric 104 and is operable to form the first quantum dot 110 at the interface 106. Gate electrode 124 is positioned on the dielectric 104 and is operable to form the second quantum dot 126 at the interface 106. Gate electrode 122 may be a barrier gate or exchange gate. Gates 108, 122 and 124 form an arrangement of gate electrodes that can be used to confine electrons in the quantum dots 110, 126, control the spin of electrons during operation, and/or alter the wavefunction of the quantum dots 110, 126 during operation. In other examples, the arrangement of gate electrodes may include more gate electrodes.

As described previously, each of the two quantum dots 110 and 126 may include multiple electrons, where a qubit is encoded using the spin of an electron isolated in each of the quantum dots (110, 126). This arrangement may be utilized to form a double quantum dot having N-M occupancy. A double quantum dot with N-M occupancy is understood to be a qubit device 120 with N electrons in the left quantum dot 110 and M electrons in the right quantum dot 126, where N may or may not be equal to M.

In some examples, a voltage bias may be applied to barrier electrode 122 to control the coupling of the qubits encoded in the spin of the electrons confined in the quantum dots 110 and 126. Furthermore, a combination of voltages applied to the arrangement of gate electrodes 108, 122, 124 may be used to control the exchange coupling between spins in each of the two quantum dots 110 and 126.

In some examples, the two-dimensional electron gas confined at the Si/SiO₂ interface can be depleted to isolate quantum dots 110 and 126 by using an electrostatic field through gates 108, 122 and 124. In other example, other surface gate electrode structures may also be employed to aid in confinement of the quantum dots. In some embodiments, further elements can be introduced at the interface to promote electron confinement, such as doped regions or dielectric regions. The overall concentration of electrons at the interface may be modified using an isolated global gate above the device (not shown), or by using an isolated global gate below the device (not shown).

FIG. 1C shows a schematic top view of another example quantum processing unit 130 according to an embodiment of the present disclosure. The quantum processing unit 130 comprises an arrangement of electrodes, including gate electrodes 132A-I (collectively referred to as gate electrodes 132) and barrier electrodes 134A-L (collectively referred to as barrier electrodes 134), for generating confining potentials for up to nine multi-electron quantum dots 136A-I.

In some examples, the quantum processing unit 130 may be formed by an array of multiple quantum processing elements 100. In such an embodiment, each of the quantum dots 136A-I in quantum processing unit 130 will be similar to quantum dot 110 and may include multiple electrons. However, the number of electrons in each quantum dot 136A-I need not be the same. A qubit may be encoded in the spin of an electron isolated in each quantum dot 136A-I.

For example, a quantum dot 136A may be formed by the confining electrostatic potential generated by the arrangement of gate electrode 132A and barrier electrodes 134A and 134C to bind a controllable number of electrons in the quantum dot 136A.

Although not shown, the quantum processing elements shown in FIGS. 1A-1C may further include one or more controllers configured to control and modify the voltages and/or biases applied to the gate electrodes 108, 122, 124, 132, 134. In particular, the controller may be used to control the voltages applied to the gate electrodes to generate a confining electrostatic potential for forming quantum dots and/or change a shape of a confinement potential of unpaired electrons or holes in the quantum dots.

### Physics of Multi-Electron Quantum Dots

Multi-electron quantum dots, like those used in the quantum processing devices 100 and 120, are often considered artificial atoms. Such multi-electron quantum dots are useful as they can create stable qubits for use in quantum processing units (e.g., quantum processing unit 130) and they are more resilient to charge noise than single electron quantum dots. Further, qubits formed in multi-electron quantum dots have a higher, tuneable tunnel coupling strength compared to single electron qubits.

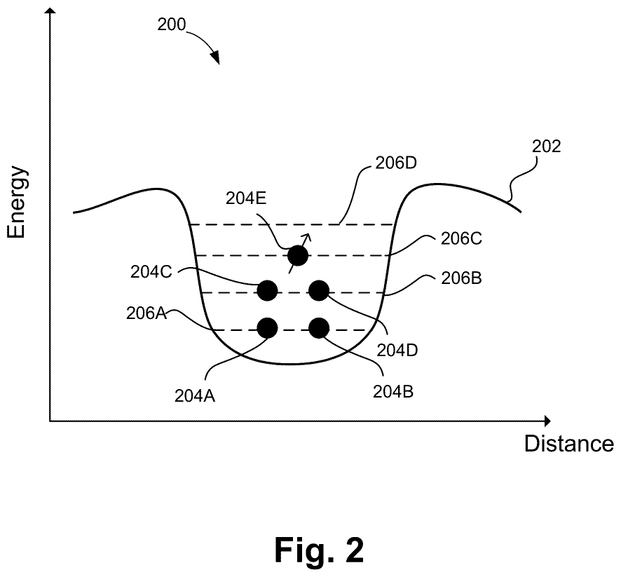

FIG. 2 is a schematic of an example multi-electron quantum dot 200 which includes five electrons 204A-E. The confinement potential (along the y-axis) as a function of distance (along the x-axis) is shown for voltages applied to an arrangement of gate electrodes, for example, gate electrodes 108, 122 and 124 in qubit device 120. As seen in FIG. 2, the confinement potential 202 in this case is a three-dimensional potential well. The nanoscale size of such a confinement well yields a discrete energy spectrum. The Si/SiO₂ interface provides one-dimensional confinement, and the two other dimensions are confined by electrostatic fields.

Generally speaking, wave equation solutions to the Schrödinger equation generate orbitals that define the electron distribution in a quantum dot. In particular an orbital is a mathematical function that describes the most probable location and wave-like properties of an electron bound to a quantum dot. The properties of these quantum dot orbitals can be analogous to the orbitals of an electron bound to an atomic nucleus. In particular, quantum dot orbitals can have quantum numbers and degeneracies, similar to atomic orbitals.

Typically, each atomic orbital is characterised by a unique set of quantum numbers, namely n, l and mₗ. The first of these quantum numbers n is the principal quantum number and denotes the electrons' energy. The second quantum number l is the orbital angular momentum quantum number. These atomic orbitals themselves are denoted s, p, d, f and so on, and they represent the probability distribution of an electron with orbital angular momentum number l=0, 1, 2, 3, . . . respectively. The third quantum number m is the magnetic quantum number and defines the degeneracy within an orbital angular degree of freedom. Degeneracy is the number of different orbital states that an electron can have and still have the same energy. The s, p, d and f atomic orbitals have corresponding degeneracies 1, 3, 5 and 7 respectively.

These three quantum numbers (n, l, mₗ) define the atomic orbitals or energy levels in the atom and are used to describe the electron configuration of the atom. The electron filling of the discrete energy levels or atomic orbitals of an atom follows the Aufbau principle, which states atomic orbitals of lower energy are filled first before filling higher energy orbitals.

The Aufbau principle is used in conjunction with the Pauli Exclusion Principle, which states that no two electrons can have the exact same quantum numbers. Thus, only two electrons can exist in a single atomic orbital defined by the quantum numbers (n, l, mₗ). A fourth quantum number namely mₛ known as the spin quantum number describes the intrinsic angular momentum of an electron i.e., the electron spin. This fourth quantum number is required to distinguish the two electrons within the same atomic orbital. Thus, these four quantum numbers (n, l, mₗ, mₛ) completely describe the quantum state of an electron in an atom.

Analogously to electrons in an atom, electrons in a multi-electron quantum dot occupy discrete energy levels. Referring back to FIG. 2, the quantum dot 200 is a multi-electron quantum dot with five electrons 204A-204E and three distinct energy levels 206A-206C. The electrons 204A-E fill up the discrete energy levels 206A-C in the quantum dot 200 defined by the confinement potential 202 in accordance with the rules of quantum mechanics. As such, two electrons can occupy a particular energy level, filling the lower energy levels before the higher energy levels. Thus, two electrons 204A-B occupy energy level 206A, and two electrons 204C-D occupy energy level 206B.

The last unpaired electron 204E is called the valence electron and the valence electron occupies energy level 206C (also called the highest occupied level) in the quantum dot 200. In aspects of the present disclosure, a qubit is encoded in the spin of this valence unpaired electron 204E.

Similarly to atomic orbitals, the quantum dot orbitals have quantum numbers that enumerate them, and have degeneracies or quasi-degeneracies-situations where more than one orbital has very similar but not identical energies.

The quantum numbers in quantum dots are different from quantum numbers in an atom, but the orbitals are analogous to atomic orbitals—i.e., quantum dots also have angular momenta designated as s, p, d and f. The degeneracies per orbital are, nevertheless, different from the atomic case. The degeneracies in a quantum dot system are 1, 2, 3 and 4, respectively.

Particularly in silicon, electrons have an additional quantum number associated with the multiple minima of the silicon conduction band. This quantum number is called valley. In quantum dots formed by electrons confined against an interface between silicon (in the (001) crystallographic direction) and SiO₂, the electron can be in either of two valley states. These valley states have an energy separation caused by a sharp interface potential, which is called valley splitting.

The first occupied energy level in the quantum dot (i.e., energy level 206A) is analogous to a fully symmetric atomic orbital, i.e., an s-type orbital. The second occupied energy level in the quantum dot (i.e., energy level 206B) is also analogous to a fully symmetric s-type orbital, but it has a higher energy because it has a different valley quantum number. The third energy level (i.e., energy level 206C) is the highest occupied energy level and is analogous to a p-type orbital. There are also higher order energy levels present in the system, which the valence electron may occupy if excited. In this example, the fourth energy level 206D, i.e., the lowest unoccupied orbital, is also analogous to a p-type orbital.

Generally speaking, in a spherically symmetric atom, there are 3 p-orbitals (pₓ, p_{y}, p_{z}) and these orbitals are degenerate—i.e., they have the same energy levels. However, in the quantum dot system 200 where the electrostatic confinement is two-dimensional, two p-type orbitals are available-pₓ and p_{y}. For example, the third energy level 206C, i.e., the highest occupied orbital, may be a pₓ orbital and the fourth energy level 206D, i.e., the lowest unoccupied orbital, may be p_{y} orbital. The choice of naming pₓ and p_{y} is arbitrary, and their directions is determined solely by the ellipticity of the quantum dot. Further, their degeneracy can be lifted by altering the shape of the confinement potential 202.

In a similar way, quantum dots with N=13 and N=25 electrons possess a single electron in the d and f quantum dot orbitals, respectively. Also, a quantum dot with N=1 electron only has an electron in the lowest, s-orbital, with the lowest valley quantum number. Similarly, a quantum dot with N=3 electrons will have one valence electron in the s-orbital, but in the higher valley quantum number.

### Tuning the Quantum Dot Shape

As described previously, aspects of the present disclosure, change the shape of the confinement potential 202, thereby allowing control over the excitation spectrum of the quantum dot. While various wavefunction modifications can be targeted to achieve said control, in certain embodiments changing the shape of the confinement potential also changes the shape of the quantum dot wavefunction. This changing in the shape of the confinement potential and/or shape of the quantum dot wavefunction can be used in one of the applications described in the following sections.

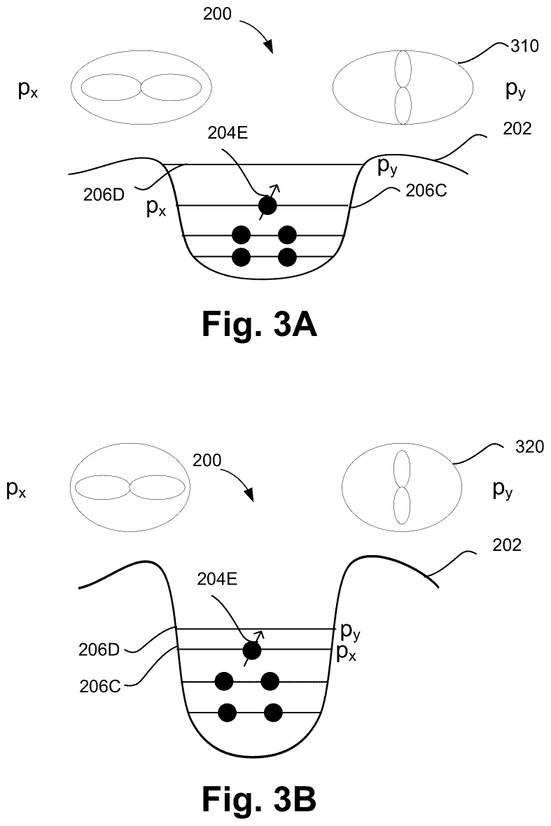

FIGS. 3A and 3B show tuning of the quantum dot wavefunction shape in two different ellipticities according to aspects of the present disclosure. In particular, FIGS. 3A and 3B show schematics of an example multi-electron quantum dot 200, along with corresponding confinement well 202 shapes and electron p-orbitals when different voltages are applied to the arrangement of gate electrodes surrounding the quantum dot 200. In these examples, the quantum dot 200 includes five electrons-204A-E.

As previously mentioned in reference to FIG. 2, a five-electron quantum dot includes four paired (and therefore inert) electrons 204A-204D that occupy the two lowest energy levels 206A-B of the quantum dot 200, i.e., two s-type orbitals, each with a different valley quantum number. The fifth valence electron 204E occupies the third energy level 206C, otherwise known as the highest occupied orbital. In this example, referring now to FIG. 3, the valence electron 204E occupies the pₓ orbital 206C. The lowest unoccupied orbital is a p_{y} orbital (206D). The choice of naming pₓ and p_{y} is arbitrary, and their direction is determined solely by the ellipticity of the quantum dot (as described previously).

A combination of DC electric fields applied through the arrangement of gate electrodes manipulates the shape of the quantum dot wavefunction—i.e., the applied DC electric fields effectively change the ellipticity of the quantum dot wavefunction. This change in the ellipticity of the quantum dot wavefunction in turn alters the energy gap between the highest occupied energy level (pₓ orbital) and the lowest unoccupied energy level (p_{y} orbital).

FIG. 3A shows the case where an electrostatic potential is applied to the quantum dot 200 via the arrangement of one or more electrodes (e.g., gate electrode 108 in FIG. 1A) to create a more elliptical quantum dot wavefunction shape 310. This increased ellipticity increases the energy gap between the pₓ orbital and the p_{y} orbital. This causes the p_{y} orbital to be an energetically unfavourable orbital for the valence electron 204E to be excited into. Thus increasing the probability of the valence electron remaining in the pₓ orbital.

FIG. 3B shows the case where an electrostatic potential is applied to the quantum dot 200 via the arrangement of gate electrodes (e.g., gate electrode 108 in FIG. 1A, or some combination of gate electrodes 132, 134 in quantum processing unit 130) to create a more circular quantum dot wavefunction shape 320. This decreased ellipticity, decreases/reduces the energy gap between the pₓ and p_{y} orbitals. This causes the p_{y} orbital to be a more energetically favourable orbital for the valence electron 204E to be excited into. Thus increases the probability of the valence electron to be in the p_{y} orbital (although still preferring the pₓ orbital). In this state, a small potential energy is sufficient to excite the valence electron 204E from the pₓ to the p_{y} orbital.

If an electrostatic potential was applied to the quantum dot 200 (via the arrangement of gate electrodes) to create a completely circular quantum dot wavefunction, the pₓ and p_{y} orbitals would become degenerate i.e., have the same energy. In this case, the probability of the valence electron being in either the pₓ or p_{y} orbital becomes equal. In this case, any quantum superposition of pₓ and p_{y} orbitals is also a stationary state for the electron 204E, and the electron 204E can change from the pₓ orbital to the p_{y} orbital without any energetic cost.

The lateral “squeezing” of the quantum dot wavefunction shape from the more elliptical to a less elliptical or circular shape, and vice versa, effectively controls the internal energy levels of the quantum dot 200.

In the particular example shown in FIGS. 3A and 3B, the lateral squeezing of the quantum dot wavefunction alters the energy gap between the pₓ orbital and the p_{y} orbital. Consequently, the likelihood that the valence electron 204E will be excited from the pₓ orbital to the p_{y} orbital is affected. This control of the energy levels allows for multiple applications to be performed on the qubit, discussed further in the application section.

It should be noted that the particular example discussed here is related to the quantum dot ellipticity and its relation to the degeneracy of different orbital states, but other forms of degeneracy can be created in the same way, such as valley degeneracy, degeneracy between two orbitals with different angular momenta (p and d, for instance) and the degeneracy between two states generated by electron-electron correlations, such as Wigner molecules. Any form of electrically-controllable degeneracy will provide the same conditions for the applications described here and can be used within the present disclosure.

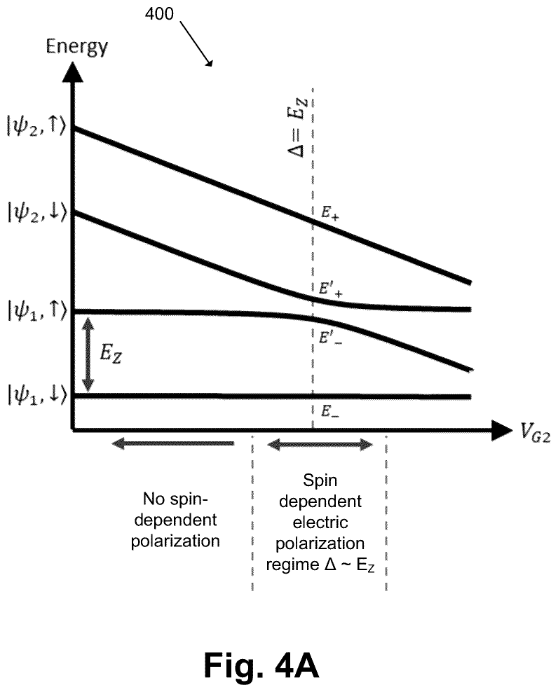

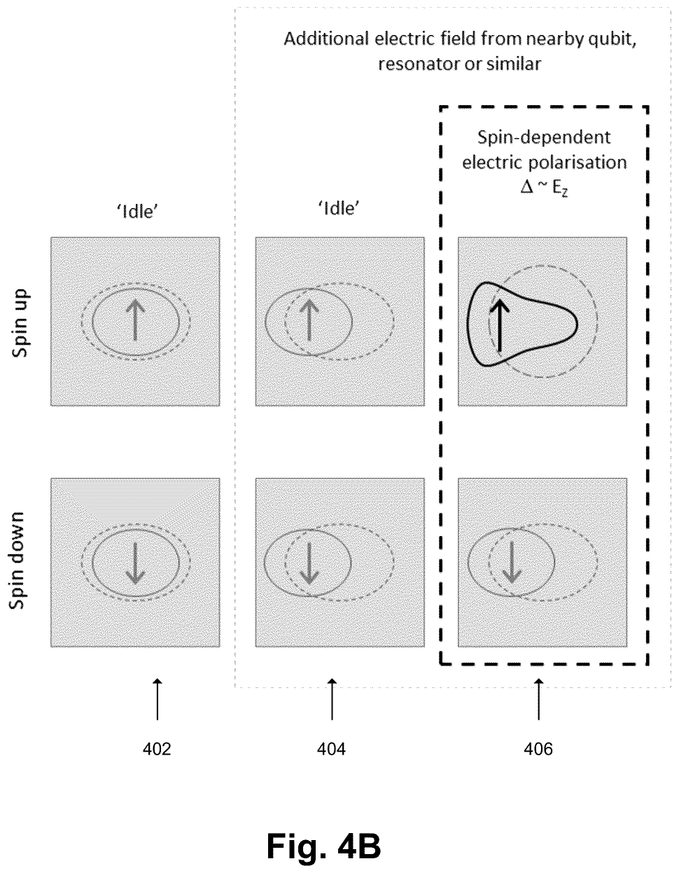

FIG. 4A shows an energy diagram 400 of the lowest four eigenstates of an electron in a quantum dot as a function of a gate voltage. In particular, FIG. 4A is a schematic energy diagram of a spin qubit as a function of gate voltage V_{G} (for example, voltage applied to gate electrode 108). In a multi-electron quantum dot, for example quantum dot 200, the valence electron 204E occupies quasi-degenerate orbital states, |ψ₁ [symbol] and |ψ₂ [symbol] with energy E₁ and E₂ respectively (shown as horizontal and sloped lines, respectively in FIG. 4A). For example, in the five-electron quantum dot 200, the orbital states |ψ₁ [symbol] and |ψ₂ [symbol] may correspond to the pₓ and p_{y} states.

The energies of two orbital states with different spins, namely, |ψ₁, ↑ [symbol] and |ψ₂↓ [symbol] , may cross and hybridise, by tuning the quantum dot ellipticity (represented here as the energy difference between states Δ), as shown in FIG. 4A. The grey vertical dashed line in FIG. 4A indicates the gate voltage at which the two orbital states with opposite spins hybridize.

Tuning the voltage of gate electrodes 108 and/or 122, alters the shape of the quantum dot 200 and results in a change in orbital energy difference Δ=E₂-E₁. If this orbital energy difference Δ decreases and approaches E_{z} (the energy gap between different spins in a given orbital state), the effect of the hybridization between for example |ψ₁, ↑ [symbol] and |ψ₂, ↓ [symbol] becomes significant.

This hybridization results in a change in the valence electron density distribution that may depend on its spin state. In FIG. 4B the density distribution of an electron is sketched in three situations-one in which the dot is configured far from the degeneracy point Δ=E_{z} (left column 402), the second situation where the dot is configured far from the degeneracy point and is subject to an additional electric field from, for example, a nearby resonator or movement of a nearby qubit (middle column 404), and the third situation where the dot is configured near said degeneracy point and exhibits spin dependent electron density distribution (right column 406).

The way in which the electronic density rearranges under changes in the quantum dot potential is the electronic polarizability. The electronic polarizability is independent of the spin state of the electron in the absence of degeneracies but becomes spin-dependent near the point Δ=E_{z}. This spin-dependent electronic polarizability is represented in the right column 406 of FIG. 4B.

The left and middle columns (402 and 404) are, therefore, situations where the spin is considered idle, while the right column 406 represents the configuration in which the control techniques described in the present disclosure can be implemented.

Although the above-described tuning techniques have been described with reference to a five-electron quantum dot, it will be appreciated that this is merely an example. The above-described tuning techniques work with any quantum dot that has one valence electron. Examples of such quantum dots include N=1, 3, 13 and 25 electron quantum dots.

### Calibration Method

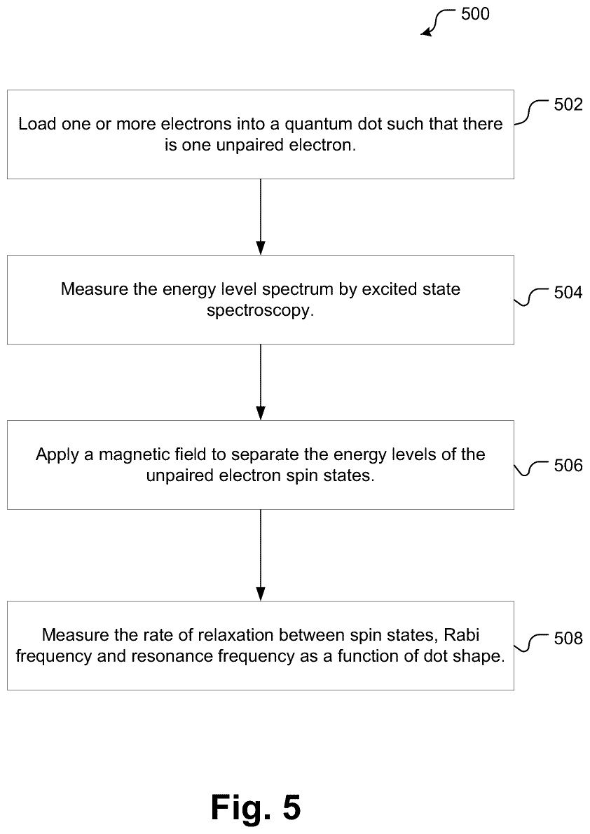

FIG. 5 is a flowchart illustrating an example method 500 performed to calibrate the quantum processing element (e.g., processing element 100, 120) before performing any of the applications described below. In particular, method 500 is performed to determine the bias configuration of the arrangement of gate electrodes to perform the various applications described herein.

The calibration method commences at step 502, where one or more electrons are loaded into a quantum dot (such as quantum dot 200) such that the quantum dot includes an unpaired electron. The electrons fill up the discrete energy levels defined by the confinement potential 202 in accordance with the rules of quantum mechanics described previously. For example, the multi-electron quantum dot 200 may have 5 electrons, with the unpaired electron occupying the highest occupied energy level, i.e., a p-type orbital.

Next, at step 504, the energy level spectrum of the multi-electron quantum dot 200 is measured by excited state spectroscopy. In particular, the energy of the excited state, i.e., the energy of the lowest unoccupied orbital 206D, is measured as a function of bias voltage applied to the gate electrodes. When the excited state 206D is degenerate with the highest occupied energy state 206C, the valence electron 204E can occupy either orbital. In particular, the example quantum dot 200 the pₓ and p_{y} orbitals are degenerate and therefore the valence electron may occupy either orbital and energy level. Further, there is no energy cost for the electron to move between the two degenerate states. This measurement is performed to determine the range of bias voltages that result in the highest occupied and lowest unoccupied energy level degeneracy.

Similarly, the excited state energy is measured as a function of bias voltage to determine the range of bias voltages (applied to gate electrodes) that yield no excitation of the valence electron from energy level 206C to excited state 206D. The regime of no excitation occurs when the energy gap between the excited state 206D and the highest occupied energy state 206C is large. This means the energy cost of exciting the valence electron is too large, and therefore the probability of such a transition occurring is negligible. At step 504, these measurements determine a region of interest in which the qubit should be operated for the different applications disclosed below. This is considered a coarse-grained measurement step.

Next, at step 506, a magnetic field is applied to the qubit to separate the energy levels of the unpaired electron spin states. In one example, the magnetic field strength is in the range of 0.01-1.5 T.

Next, at step 508, the rate of relaxation between the spin states of the unpaired electron as a function of dot shape is measured. In particular, this measurement may be done by determining the relaxation time of the spin states of the unpaired electron at each voltage bias determined in the range of voltage biases during the coarse-grained measurement (i.e., step 504). Near to the degeneracy point, the relaxation rate will show a maximum. This calibration step is called a fine-grained measurement step.

These calibration steps together identify the special points of operation for a given qubit device for use in a given application.

The same methods described above may be adapted for the case of hole-based spins in quantum dots. This is done by adjusting the ranges of voltages and the dot shape in order to control the excitation spectrum of the holes, recognizing that the microscopic nature of these excitations will be different due to the different parameters of the valence band, compared to the conduction band. Moreover, in lieu of a valley degree of freedom, holes would present an additional band, associated with the coupling between light holes and heavy holes (with the energy level ordering dependent on the particulars of the choice of materials and operation voltages).

### Applications

### Fast EDSR

As described previously, tuning the quantum dot wave function affects the energy of the excited state relative to the highest occupied energy state-effectively controlling the internal energy levels of the quantum dots system. This allows for faster EDSR spin rotations controlled via proximity of different symmetry excited states in a quantum dot.

One example of such electrostatically tunable degeneracy is the case of a dot with controllable ellipticity. However, other examples previously discussed are also valid, such as valley excitations or interaction-induced transitions.

In the particular example of a nearly circular quantum dot with five electrons, by tuning the quantum dot wavefunction shape between the elliptical shape 310 and the more circular shape 320, the unpaired electron 204E can move between the two states (pₓ orbital and the p_{y} orbitals) with controllable efficiency. By driving this change in quantum dot wavefunction shape at the right frequency, it is possible to achieve resonance and Rabi oscillations (i.e., make the spin of the valence electron 204E flip) at a faster rate. Moreover, the Rabi frequencies in the multi-electron qubit can be enhanced and maximised when the spin-orbital states |ψ₁, ↑ [symbol] and |ψ₂↓ [symbol] are nearly degenerate (see FIG. 4), i.e., when Δ≈gμ_{B}B. Where g is the electron g-factor, μ_{B} is the Bohr magneton and B is the applied external magnetic field.

Accordingly, by using the above-described technique, qubits can be electrically controlled without the need for micro-magnets. If the gate electrode voltages are selected to form a quantum dot with no orbital degeneracy 310, no enhancement of EDSR is observed, and only the very weak SOC of silicon participates in the spin flipping. Alternatively, when the quantum dot 200 is tuned near a configuration with orbital degeneracy 320, the additional internal movement of the valence electron 204E (for this particular example between pₓ and p_{y} orbitals) leads to a significant enhancement in EDSR Rabi frequency. As such, fast EDSR is achieved when the pₓ and p_{y} orbitals are degenerate, or nearly degenerate. This occurs for any value of the static magnetic field, but the exact bias configuration must be recalibrated if the static magnetic field is changed.

Quantum dots with a single electron may also present a tunable excitation energy spectrum from other internal properties of the quantum dot, including anharmonicity (i.e., the deviation of a system from being a harmonic oscillator), interface disorder and strain effects. These quantum dots would also present a voltage bias configuration that allows for enhanced EDSR control.

In one example, the enhancement of Rabi frequency is determined and demonstrated in a multi-electron quantum dot, with 3 electrons in a 3-1 occupancy double dot system (similar to system 120 shown in FIG. 1B). Importantly, the double dot system does not include any micro-magnets to facilitate electric drive for spin rotations. Excited state spectroscopy was carried out to measure the excitation spectrum with respect to electrode 122 between the two quantum dots 110 and 126, see calibration method 500, step 504.

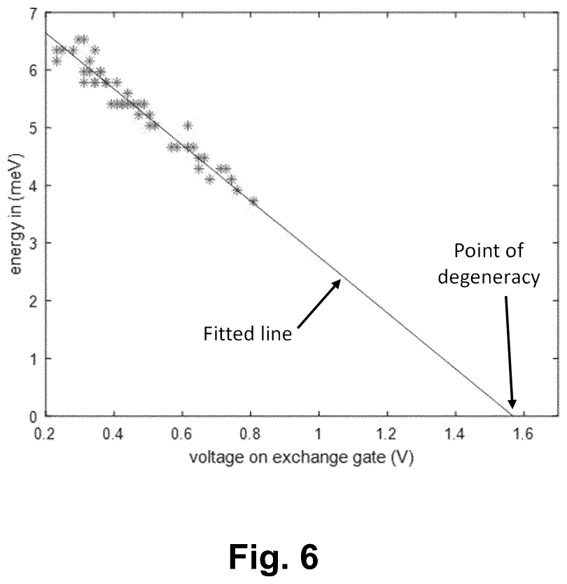

FIG. 6 shows the excited state energy of this system as a function of the voltage (V) on exchange gate electrode 122 in between two quantum dots 110, 126 in a (3,1) occupied double quantum dot system. It is seen that the excitation energy converges to zero, indicating the point at which the fast EDSR will be reached. In this example, the number of electrons indicates that the degeneracy will occur between the excited valley state of the s orbital and the lower valley state of the p orbital, differently to the previous example that leveraged the degeneracy of pₓ and p_{y}.

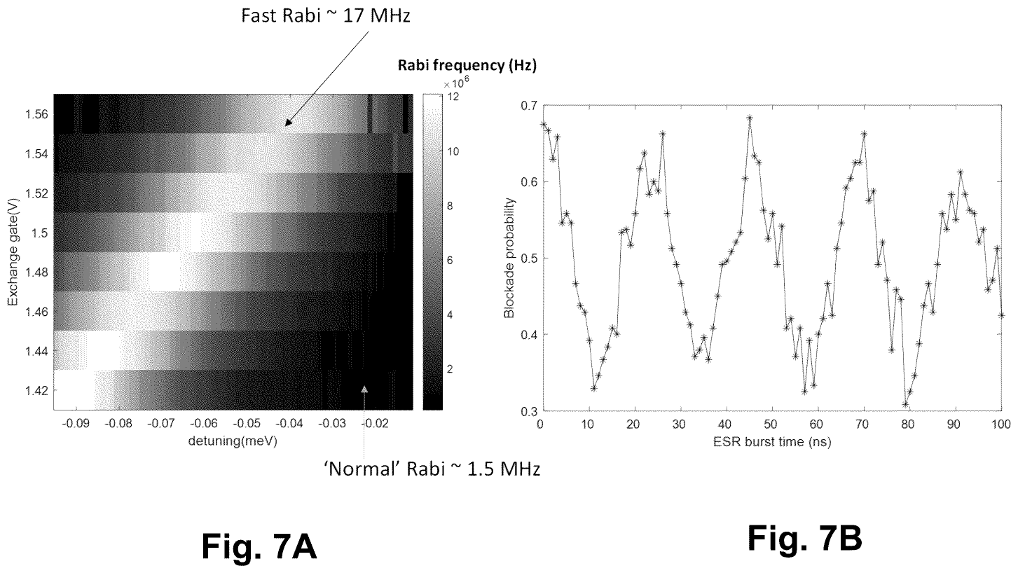

FIG. 7A shows the measured Rabi frequency as a function of energy detuning between adjacent quantum dots (x-axis) and exchange gate bias (y-axis) near the point identified by the excited state spectroscopy. It shows the region of maximum Rabi frequency, where the Rabi rotations are approximately 8 times faster than a “standard” bias configuration. In particular, this figure shows that the Rabi frequency increases as the exchange gate voltage increases towards the exchange gate bias that results in degeneracy of the energy/orbital states.

FIG. 7B shows the probability of measuring a spin-up in the 3-electron quantum dot as a function of electron spin resonance (ESR) burst time showing coherent Rabi oscillations at a rate of approximately 10 MHz. The Rabi frequency was observed to be the highest when the bias configuration created a degeneracy between the energy of the lower orbital energy and the energy of the higher orbital state.

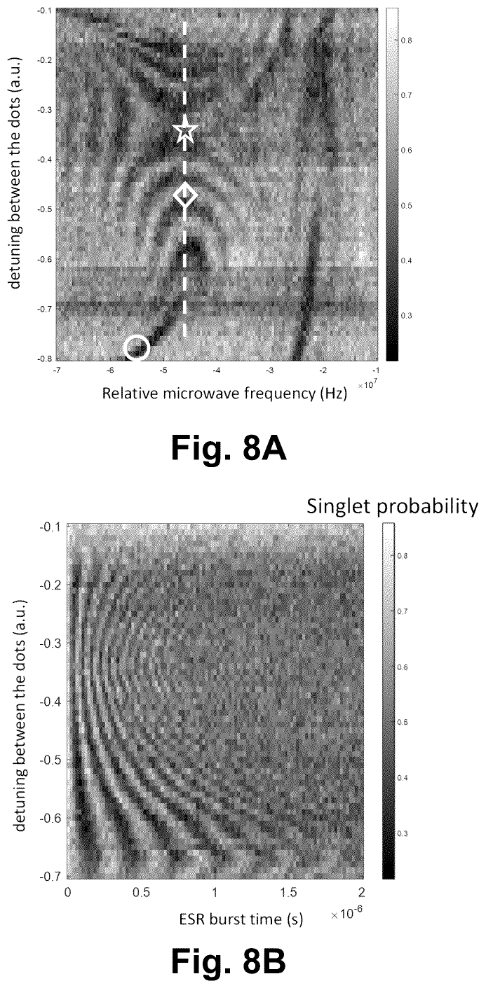

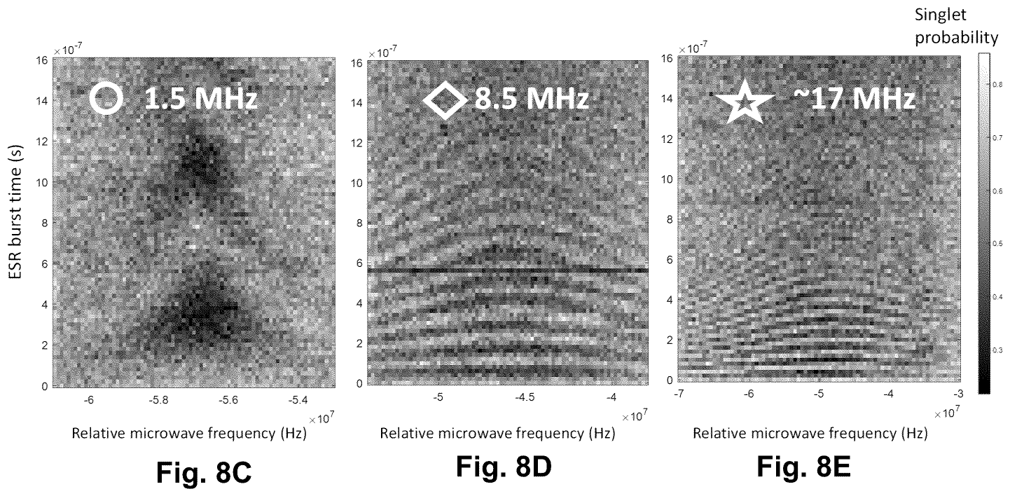

FIGS. 8A and 8B show a map around the point of maximum Rabi frequency. In particular, FIG. 8A shows the spin-up probability as a function of microwave frequency (x-axis) and detuning (y-axis) between the two quantum dots 110 and 126 in the qubit device 120 in a 3-1 electron occupancy. FIG. 8B shows the spin probability as a function of microwave burst time (x-axis) and detuning (y-axis) between the two quantum dots 110 and 126 in the qubit device 120 in a 3-1 electron occupancy.

FIGS. 8C-8E show the spin-up probability as a function of microwave frequency (x-axis) and microwave burst time (y-axis). In particular, FIG. 8C shows a Rabi oscillation frequency of 1.5 MHz, FIG. 8D shows a Rabi oscillation frequency of 8.5 MHz and FIG. 8E shows a Rabi oscillation frequency of approximately 17 MHz, as measured at the points represented in FIG. 8A as a circle, square and star, respectively. These plots determine the exact speed-up provided by this degeneracy condition.

It can be seen from these figures that the speed-up in the Rabi frequency by varying the detuning between the two quantum dots 110, 126 is more than a factor of 10.

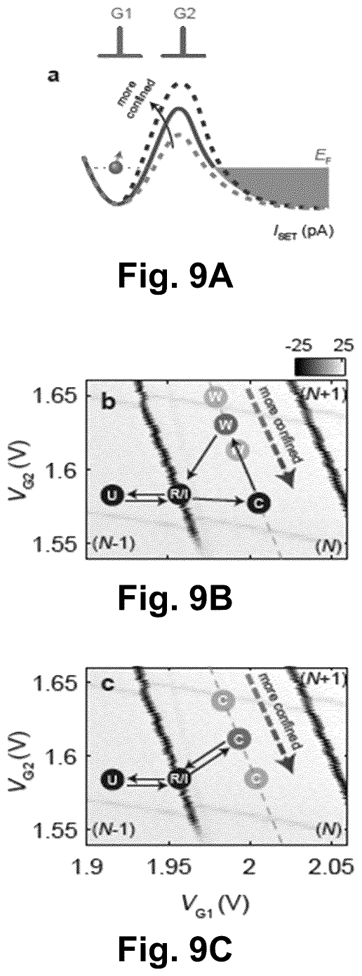

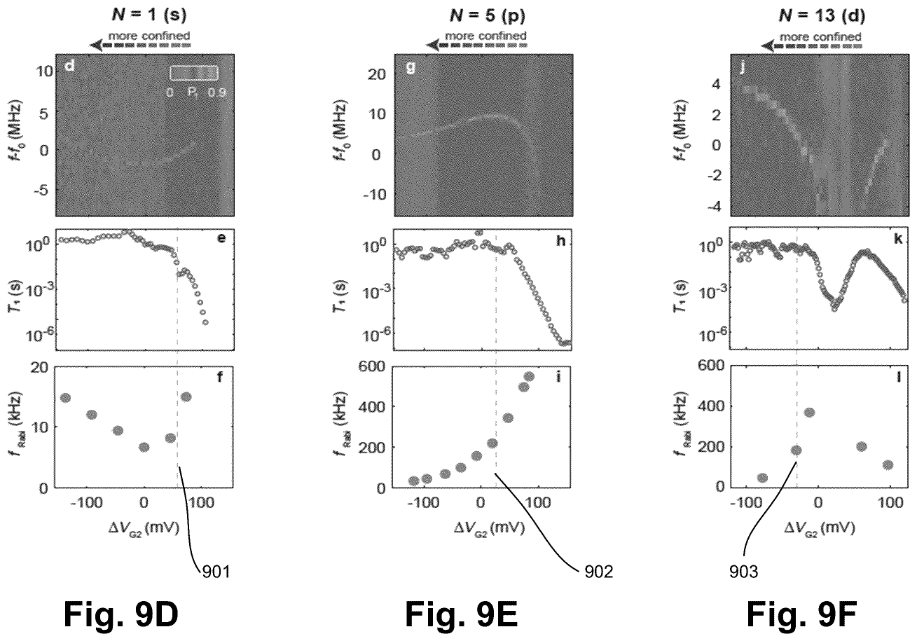

In another example, the enhancement of Rabi frequencies is determined and demonstrated in a multi-electron quantum dots in the presence of a micro-magnet. In this system, the gate voltage (G2) varies in order to change the quantum dot shape and tunnel rate to the reservoir. A compensating voltage is applied to a second gate (G1) to maintain the quantum dot energy level relative to the fermi level (E_{F}). FIG. 9A is a schematic representation of the energy band diagram for such a quantum device.

The spin relaxation time Ty of such a quantum device is measured using a pulse sequence as shown in FIG. 9B. The voltage bias configurations marked as U, R/I, C and W correspond respectively to the point of unloading, initialising/reading out, controlling and waiting for each experiment.

Further, the Rabi frequency of the device is measured using a pulse sequence as shown in FIG. 9C. The qubit control point varies along the dashed line inside the charge stability diagram, parallel to the charge transitions, with electron occupancy either N=1, 5 or 13.

FIGS. 9D-9F show the experimental results for a quantum dot with electron occupancy either N=1, 5 or 13, respectively. Each of FIGS. 8D-8F shows the non-linear Stark shift, spin relaxation time (T₁) and Rabi frequency for comparison between the quantum dots with different electron occupancies.

For the N=1 electron case in FIG. 9D, a non-linear Stark shift of qubit resonance frequency is observed when the qubit control point changes along dashed line in FIGS. 9B and 9C. At certain voltage levels, the resonance frequency shifts dramatically and eventually qubit readout is unachievable. Further, for the N=1 electron case in FIG. 9D, correlation is observed between the magnitude of the differential ESR resonance frequency (f-f₀) and qubit relaxation time T₁. Further still, for the N=1 electron case in FIG. 9D, correlation is also observed between f-f₀ and Rabi frequency f_{Rabi}.

There is a qualitative correlation between the maximum Rabi frequency and the non-linearity of the Stark shift shown in FIG. 9E for the case N=5 and in FIG. 9F for the case of N=13 electrons. A clear correlation between the drop in Ty and regions with a highly non-linear Stark shift is similar to previous literature. This indicates the presence of an excited orbital or valley state near the Zeeman excitation, resulting in a reduction of T₁.

Since the virtual excited state (either valley or orbital) plays an essential role in EDSR, the excitation energy directly influences the qubit Rabi frequencies. Performing the pulse sequence in FIG. 9C, yields an enhancement for the Rabi frequencies of p and d orbitals correlated to the drop in T₁.

The Larmor frequency and the Rabi frequency as a function of the change in gate voltage (ΔV_{G2}) may be non-monotonic in some charge configurations, with discernible correlation between their extrema. These are indications that the p and d spins are coupled to excited states of a different nature to those for s orbitals. There are no charge transitions—or visible features in the charge stability diagram—indicating the ground state configuration is left unchanged. Note that some Rabi frequency enhancement is also observed for the N=1 electron configurations, but it is an order magnitude smaller that for the N=5 and 13 electron cases.

Examples of advantageous qubit operation voltages, where a balance exists between fast Rabi oscillation and long spin lifetime, shown in FIGS. 9C-9D by dotted vertical lines 901, 902 and 903. The corresponding f₀ for a quantum dot with either N=1, 5 or 13 electrons is f₀=41.835 GHz, 41.870 GHz and 41.826 GHz respectively.

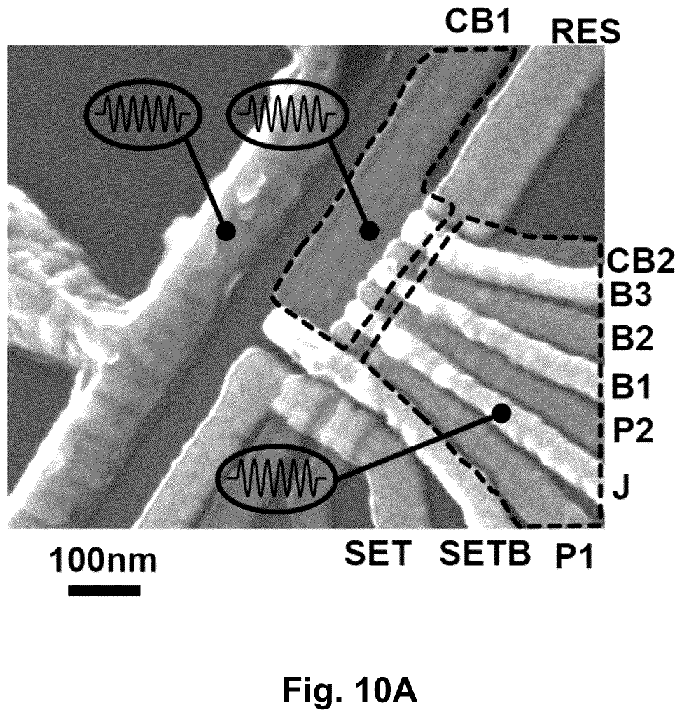

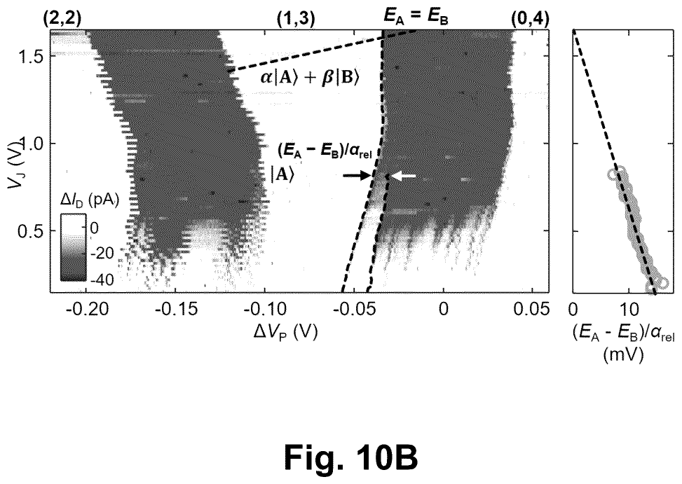

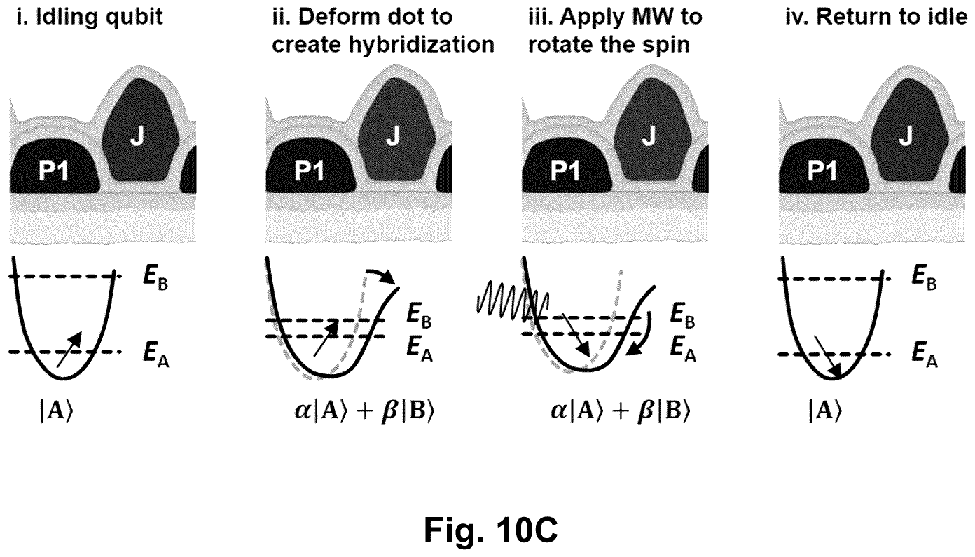

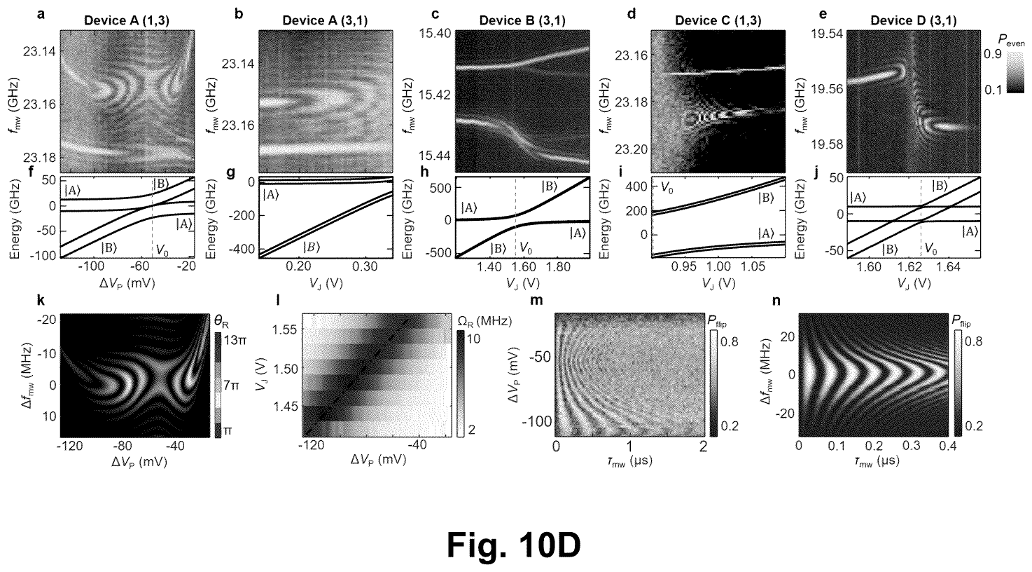

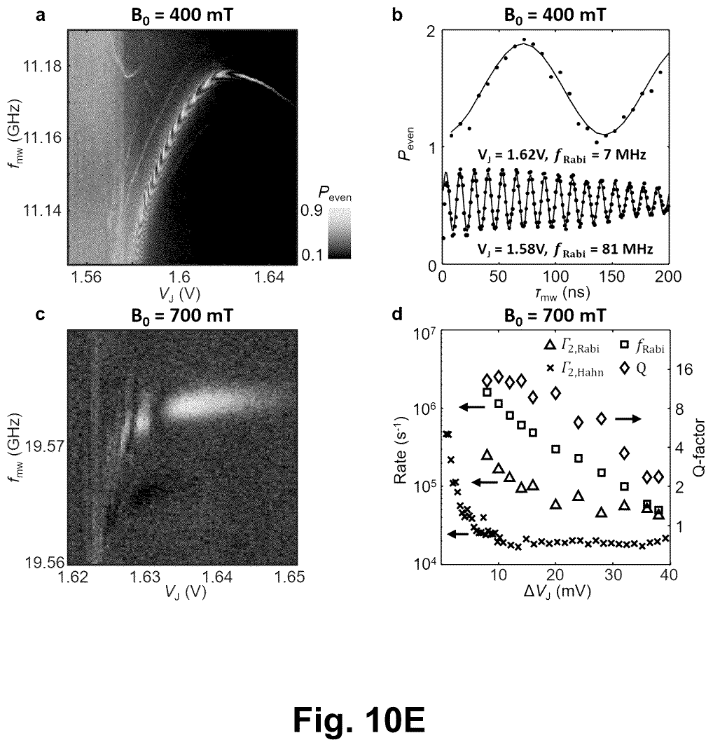

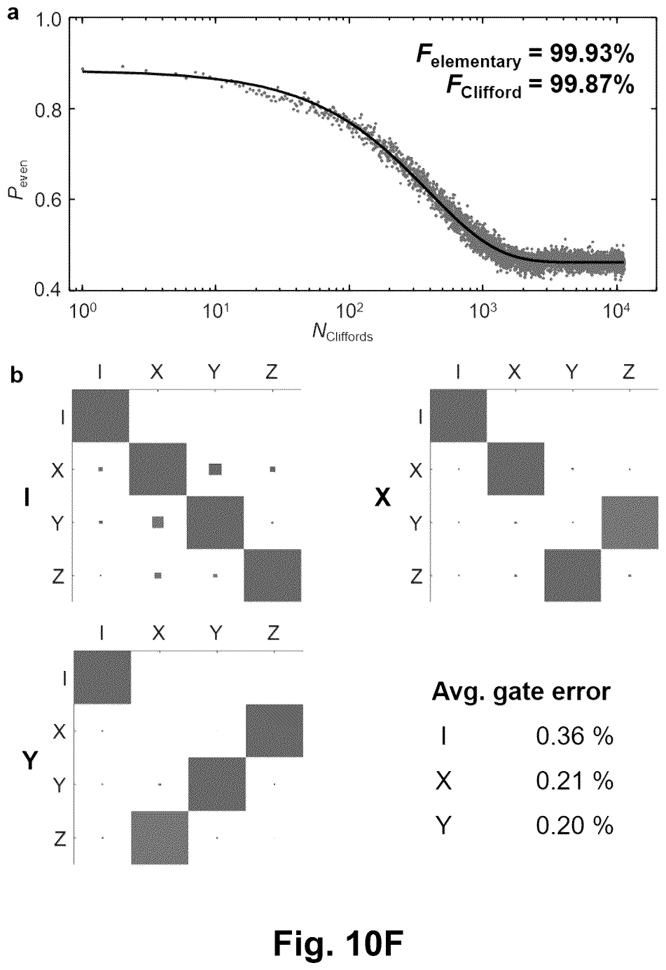

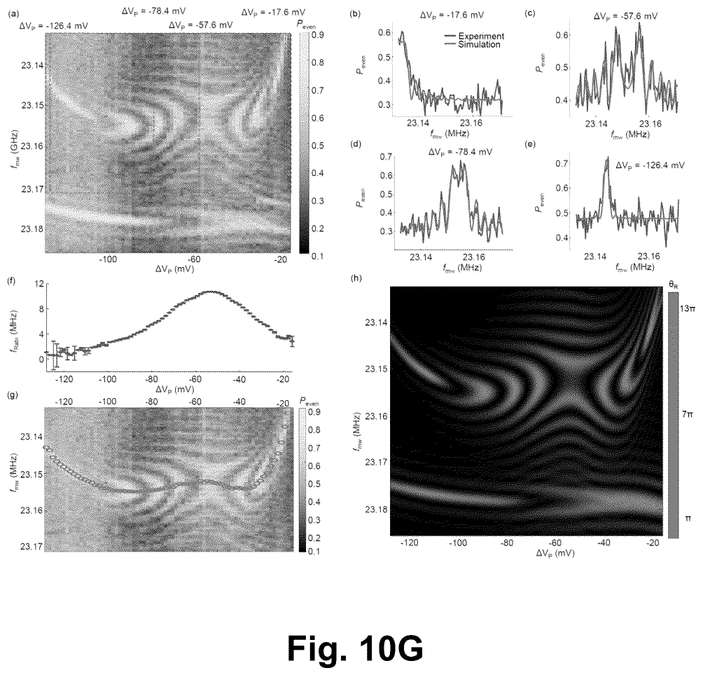

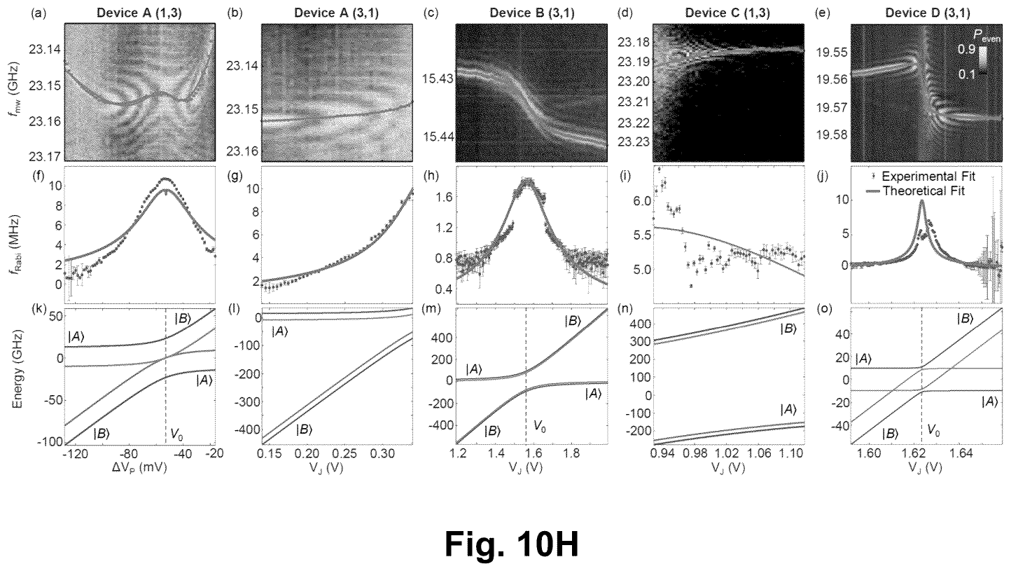

FIGS. 10A-10H illustrate a realisation of improved (fast) EDSR using the quantum systems and methods described herein. A scanning electron micrograph of a quantum dot device is shown in FIG. 10A.

FIG. 10B shows an excited state spectroscopy of an isolated double quantum dot containing 4 electrons, as a function of V_{J} and an interdot voltage bias ΔVₚ. Energies E_{A} and E_{B} are fitted to step increases in an interdot tunnel rate, indicating the occurrence of ground and first excited states.

Qubit control is achieved by deforming the quantum dot to achieve a controllable orbital degeneracy. FIG. 10C illustrates a control sequence for the quantum dot using the lateral J gate, including: an idle state being purely spin-only (e.g., at (i) and (iv)); and a control state being a spin-orbit mix.

FIG. 10D shows a Pulsed Electron Spin Orbit Spectroscopy (PESOS) map (a), consisting of the probability of measuring a spin flip after a burst of microwave of fixed power and duration, while varying the microwave frequency and a gate electrode voltage bias. The power and duration of the burst are roughly calibrated to correspond to a I-rotation for a pure spin state. Fringes appear as a function of gate voltage as the spin-photon coupling becomes more intense, and the spin being rotated by several x. Additional PESOS maps (b)-(e) may be obtained from measurements taken for different devices, varying materials, charge configurations, magnetic fields and/or for other variations.

In the example illustrated by FIG. 10D, (f)-(j) shows a series of four-level models that best reproduce the data from maps (a)-(e), to demonstrate the variety of crossing regimes and their impact on the spin dynamics. A simulated PESOS map (k) is obtained by modelling the spin-orbit qubit as a two-level system with voltage-dependent Rabi and Larmor frequencies to fit the measured PESOS map. Rabi frequencies extracted from the fitted simulations are shown by (l). Also illustrated are measured Rabi oscillations over time as a function of ΔVₚ, confirming the interpretation of the Rabi speed-up (i.e., as (m)), and measured Rabi chevron from device D, where the qubit is driven all-electrically via the gate CB1 (i.e., as (n)).

FIG. 10E shows a PESOS map (a) at an external magnetic field of 400 mT measured with square pulses. At 400 mT the resonance can be tracked until very near the degeneracy point, resulting in an increase in Rabi frequency of almost three orders of magnitude. Also shown in (b) are Rabi measurements at V_{J}=1.62 V resulting in 7 MHZ oscillations (offset for clarity) and V_{J}=1.58 V resulting in 81 MHz oscillations. (The Rabi frequency becomes immeasurably low for V_{J}>1.65 V). A PESOS map at 700 mT measured with Gaussian pulses is also illustrated in (c). At 700 mT the Rabi speed-up is more modest, but the qubit frequency is also less strikingly affected by electric field fluctuations, resulting in an overall more precise qubit operation compared to 400 mT. Shown in (d) are Rabi frequency (squares), Rabi decay rate (triangles), and Q-factor (diamonds) increase with proximity to the degeneracy point, with Q-factor reaching an optimal value at ΔV_{J}=13.6 mV. The Hahn echo (see Extended Data) coherence decay rate (crosses) increases only very close to the degeneracy point.

FIG. 10F shows measurements of single qubit gate fidelity via randomised benchmarking on the Clifford set (i.e., in (a)). The average elementary gate and average Clifford gate have 99.93% and 99.87% fidelity, respectively. Also shown in (b) is the fidelity and errors associated with the individual elementary gates as characterised with gate set tomography. Projected populations are displayed as areas with a respective polarity. Concentric squares in the top left position of the first panel represent populations of 1.0, 0.1, 0.01, and 0.001.

FIG. 10G illustrates a PESOS map (a) for Device A in the (1,3) configuration. The dotted lines indicate examples of line cuts. Plots (b)-(e) show line cuts of pₑᵥₑₙ oscillations taken at the indicated dotted lines in (a). Traces indicate the experimental data and corresponding fitted lines based on Eq. 4. Shown in (f) is the extracted Rabi frequency f_{Rabi} as a function of voltage ΔVₚ. Error bars of the fit are also shown. Shown in (g) and (h) are, respectively, the fitted qubit dispersion f₀ superimposed onto a PESOS map, and a simulated PESOS map based on fitted traces shown in (b)-(e).

FIG. 10H illustrates PESOS maps (a)-(e) with both the fitted center frequency f₀) (dots) and the fitted qubit dispersion from the four-level model (lines). Only the relevant qubit of study is shown. Shown in (f)-(j) are the extracted Rabi frequencies f_{Rabi} from the fitting to the corresponding PESOS map and the fitted Rabi frequencies from the four-level model. We note that for (j), the error bars extend below f_{Rabi}=−5 MHz but are not shown in order to highlight the actual range of Rabi frequencies. Both the positive and negative error bars are of the same magnitude. The resultant four-level energy diagram from the fitted parameters are shown in (k)-(o).

### Spin Relaxation

Preparation of a qubit into a well-defined initial state is one of the key requirements for a quantum computational algorithm. Moreover, re-initialisation is important for full scale quantum computation operations. Typically, initialisation, or re-initialisation, is achieved through an initialisation protocol that relies on the relaxation of the qubit to a thermal state determined by the residual coupling to the environment. Such passive protocols are inherently slow.

Fast and accurate qubit initialisation is advantageous in large-scale quantum computing, where it might be necessary to initialize a qubit, perform operations on the qubit and then reinitialize the qubit for the next operation.

According to some aspects of the present disclosure, tuning the quantum dot shape allows for fast initialisation (and re-initialisation). By applying DC bias voltages to the gate electrodes, the quantum dot shape can be tuned such that the spin relaxation time is either enhanced or decreased. For example, the middle chart in FIG. 9F shows a plot of the spin relaxation time T₁ (y-axis) measured in seconds for various gate voltages (x-axis) for a 13 electron quantum dot 100. The spin relaxation time remains approximately constant for gate voltages between −100 mV and approximately −10 mV, but is much faster for gate voltages near 25 mV. In order to reinitialise the quantum dot with 13 electrons, a gate voltage of 25 mV could be applied in a pulse, which decreases the confinement potential, brings the qubit close to the degeneracy state, and consequently relaxes the electron spin on the time scale of approximately 10-5 seconds. Note that the values of the gate voltages depend on the context and need to be calibrated for each specific dot configuration.

### Dipolar Intermediate-Distance Coupling

Semiconductor spin qubits have now reached high enough figures of merit to envision error-corrected architectures for quantum information processing, but several outstanding challenges remain to be solved before a viable quantum computing processor can be demonstrated in silicon. One such challenge relates to the placement of quantum dots on a processor chip. It is known that exchange interactions between qubits decay exponentially with quantum dot separation, meaning that the quantum dots need to be closely and precisely placed, tens to hundreds of nanometres apart. If arranged in a dense two-dimensional qubit array, it becomes extremely difficult to include gates, necessary for control and readout, to quantum dots in the centre of the array. Furthermore, such a dense packing of quantum dots and control electronics implies a rate of heat dissipation that is currently incompatible with the cryogenic temperatures necessary for qubit coherence.

Aspects of the present disclosure utilize the SOC of the materials of the semiconductor device or the field inhomogeneity of a micro-magnet to create a coupling between the spin of an electron and its orbit within a quantum dot. The coupling between orbital and spin degrees of freedom of the electron (or multiple electrons) in a quantum dot can be leveraged for applications relating to controllable interactions between spins. This type of interaction is important for quantum information processing, enabling the control of the entangled quantum states of two qubits, including two-qubit quantum gates that are necessary for universal quantum computation.

One example of this application of the coupling between spin and orbital degrees of freedom for qubit-qubit interaction is intermediate-distance dipolar coupling between qubits. Intermediate-distance dipolar coupling relies on Coulomb repulsion between the unpaired electron in one quantum dot with unpaired electrons in other quantum dots. If the unpaired electron in one quantum dot acquires a different orbital configuration, depending on its spin, a Coulomb repulsion can be created between that unpaired electron and unpaired electrons in surrounding quantum dots (dependent on the spin states of those electrons). This can be used to perform conditional operations on qubits.

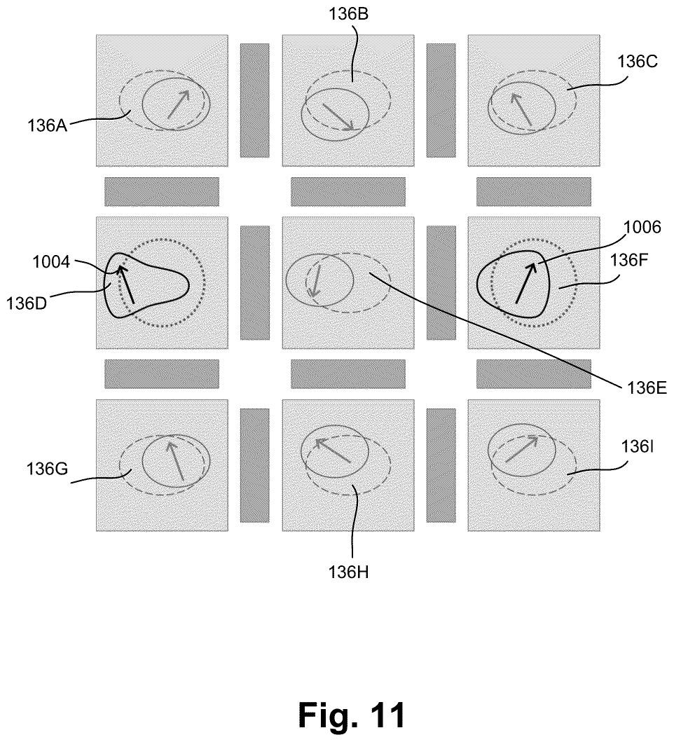

FIG. 11 shows a schematic structure of the quantum processing unit 130 with neighbouring qubits interacting via intermediate-distance dipolar coupling In this example, at least some of the quantum dots 136A-I are quantum dots with one unpaired electron in the highest occupied state of the quantum dot. In some examples, the quantum dots 136A-I may have the same number of electrons, whereas in other examples, the quantum dots may have a different number of electrons, where at least some of the quantum dots have unpaired electrons in the outer orbital.

For a particular bias range where the highest occupied state and lowest unoccupied state in the quantum dot are nearly degenerate, the unpaired electron in a quantum dot can occupy a different position depending on its spin state. For example, when qubit 1004, i.e., the valence electron in quantum dot 136D is in the spin-up state it occupies a different position in the quantum dot potential compared with a quantum dot that has a qubit in the spin-down state (e.g., see quantum dot 136A). This creates the condition for spin-dependent electronic polarizability and facilitates intermediate-range spin interactions via dipolar coupling between distant qubits.

A combination of DC electric fields/voltage biases applied to the arrangement of gate electrodes (132 and 134) changes the shape of the confinement potential and in effect tunes the quantum dot shape in accordance with aspects of the present disclosure. In one example, the shape of quantum dot 136D is tuned such that qubit 1004 is in the spin-up state and therefore occupies a certain position in the quantum dot's confinement potential.

This change in position of qubit 1004 dependent on its spin state results in either a stronger or weaker Coulomb repulsion to the surrounding quantum dot electrons. In this example all the surrounding qubits, except for a target qubit 1006, are tuned via DC voltage biases applied to the arrangement of gate electrodes such that their internal orbital energy levels are far from degeneracy and therefore the spin states of these other qubits are insensitive to this Coulomb repulsion.

Coupling the spins in qubit 1004 and qubit 1006 can be achieved by tuning the shape of the target quantum dot confining potential 202 to the point where the position of the qubit electron wavefunction becomes spin-dependent. In this configuration, intermediate-range spin-spin coupling can be achieved between the two qubits. For example, a spin flip in the first qubit changes the electron position which then shifts the position of nearby electrons through Coulomb repulsion, however it only results in a spin resonance frequency change in the target qubit which has been tuned to the bias region supporting spin-dependent electric polarizability.

It will be appreciated that the control or the target may be one or more qubits, allowing for multi-qubit gate implementations. It will also be appreciated that the quantum dots may have one or more electrons and that the quantum dots may have the same number of electrons or a different numbers of electrons without departing from the scope of the present disclosure.

In other examples, there may be a plurality of quantum dots between quantum dot 136D and quantum dot 136F, and thus a plurality of qubits between qubit 1004 and qubit 1008 can be turned off, enabling dipolar interactions between quantum dots on a chip that are not the nearest neighbours, or that are nearest neighbours but are too distant from each other to enable interdot tunnelling. The particular maximum distance for this interaction depends on the dielectric properties of the material stack adopted.

Each of the plurality of qubits between qubits 1004 and 1008 may experience a dipolar coupling with qubit 1004. The strength of this coupling may be controlled by tuning the shape of the quantum dots between qubit 1004 and qubit 1008, such that their relative internal energy levels are far from degenerate and are therefore not strongly affected by the dipolar interaction.

One example of an operation that can be performed on qubits using intermediate-distance dipolar coupling is a conditional Z rotation, in which one of the qubits (target qubit, e.g., qubit 1008) acquires a rotation around the Z axis (quantisation axis) that depends on the spin state of the electron in a different quantum dot (control qubit, e.g., qubit 1004). This is caused by the fact that the two possible quantum states of the control qubit 1004 (spin up or down) have different positions within the dot's confinement potential well. As a consequence, the repulsion between the control electron 1004 and the target electron 1008 is dependent on the spin state of the control qubit 1004. In consequence of the Stark shift (electric field dependence of spin frequency) of the target qubit, this results in a difference between precession frequencies of the target qubit, conditional upon the spin state of the control qubit.

The description of the spin-spin coupling reported above is based on the fact that the position of the electron within a quantum dot potential can change depending on the spin state. However, these shifts in position of the electron can also result from quantum fluctuation of the electron position, instead of the physical shift in electron position (virtual transitions). If these fluctuation are different depending on the spin of the electron, the same effect is achieved (with only a quantitative change in the intensity of this long-range coupling).

### Long-Distance Coupling Through Spin-Photon Conversion

Another technique to overcome the aforementioned distance issues is to include multiple nodes in a quantum computing system where each node includes a limited number of quantum dots and their associated circuitry. Quantum processing unit 130 is an example of such a node. Similarly, the double dot device 120 is another example node. The nodes may be connected to each other, alleviating overall density issues while still allowing quantum computation to be performed. To do this, the outer edge qubits of one node will need to be coupled with the corresponding outer edge qubits of another node. A leading technique for coupling the edge qubits across nodes is via microwave resonators and spin-photon coupling.

However, direct spin-photon coupling between an electron spin and a microwave photon is inherently challenging due to the small magnetic dipole interaction between the electron spin and microwave photon. Further, up to now, micro-magnets or nano-magnets have been fabricated on-chip in order to achieve spin-orbit coupling, but this is a complex fabrication process that poses new challenges when scaling up to hundreds of qubits.

As the magnetic dipole interaction between the electron spin and microwave photon is small, electrical coupling between the electron spin and microwave photon is preferable. By using the quantum dot shape tuning techniques of the present disclosure, electrical coupling between a qubit and a photon can be created and enhanced.

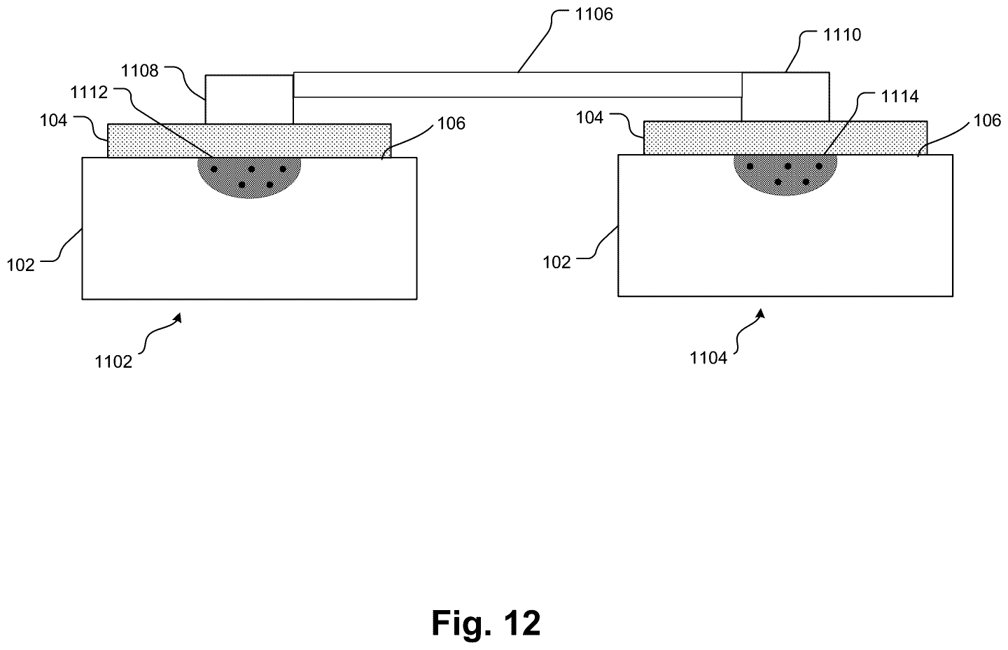

FIG. 12 shows a general architecture for connecting two long distance quantum processing elements 1102 and 1104 (e.g., on two adjacent quantum processing nodes) through a microwave resonator 1106. Each quantum processing element 1102, 1104 may be a single quantum dot as shown in FIG. 1A or a double quantum dot as shown in FIG. 1B. In the example shown in FIG. 12, each quantum processing element 1102, 1104 is a single quantum dot. However, this can be easily replaced by double quantum dots. Further, the two ends of the microwave resonator 1106 are connected to gate electrodes 1108, 1110 of the processing elements 1102, 1104.

The resonator 1106 generates an electric field. In the presently disclosed system, the quantum dots 1112, 1114 are coupled to this electric field of the resonator 1106 and experience a modulation of their confinement potential at the frequency of the resonator mode fc. This modulation in the confinement potential modulates the shape of the wavefunction of the unpaired electron trapped within, which can decrease or increase the gap between energy levels (depending on the modulated shape). If the modulation of the shape of the quantum dot is such that it is close to the degeneracy point, the spin-orbit coupling (SOC) becomes enhanced which allows the spin of the quantum dot 1112 or 1114 to be directly coupled to the superconducting microwave resonator 1106.

### Noise Resistant Exchange

The method of tuning the quantum dot shape has several applications. One such example is to provide noise resistant exchange interaction between two qubits.

Traditionally, in order to control exchange interaction, voltage biases can be applied to intermediate electrodes, for example 122, placed in between the electrodes used for quantum dot accumulation, for example 108, 124. For electrons confined in adjacent quantum dots, the exchange energy can be reduced by decreasing the bias on this intermediate exchange electrode, which increases the potential energy barrier between the quantum dots. Conversely the exchange energy can be increased by increasing the exchange electrode bias. Typically, the bias on this gate would be kept low and only increased for a short duration in which you want the qubits to interact, for example when executing a two-qubit quantum gate operation.

The exchange energy between adjacent quantum dot electrons is exponentially dependent on the exchange electrode voltage bias. This sensitivity enables control over a large range of exchange energy for small voltage bias, however any noise that exists in the voltage bias signal, for example from the control electronics, has a large impact on the exchange energy. This can lead to reduced fidelity of quantum operations and errors in quantum computations. Accordingly, an improvement is desirable.

Aspects of the present disclosure can be utilised to create noise resistant exchange between two adjacent qubits and in particular two electron spin qubits belonging to two adjacent multi-electron quantum dots as shown in FIG. 1B.

In some examples, the valence electron from one of the double quantum dots (e.g., quantum dot 110) is shuttled to the second quantum dot (e.g., quantum dot 126) via spin shuttling or exchange mediated coupling such that a two-qubit operation is performed in a single quantum dot. Operating in such a way removes the noise typically introduced via exchange interactions since the electrons involved in the interaction are located in the same physical quantum dot.

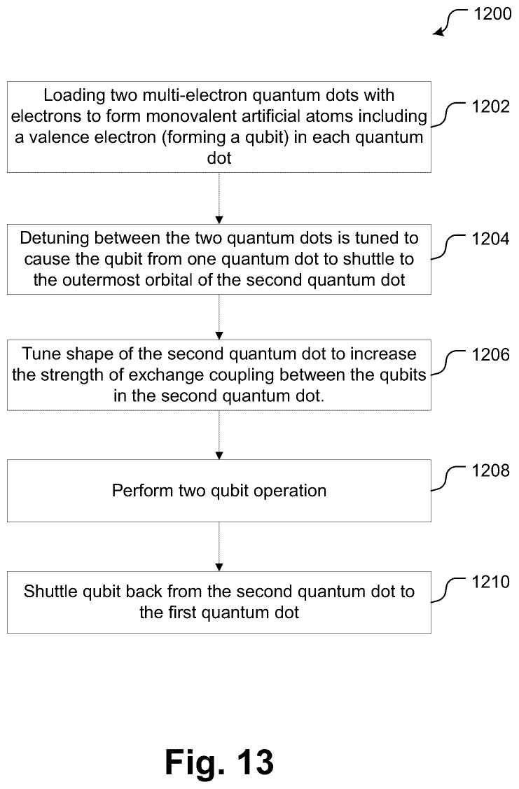

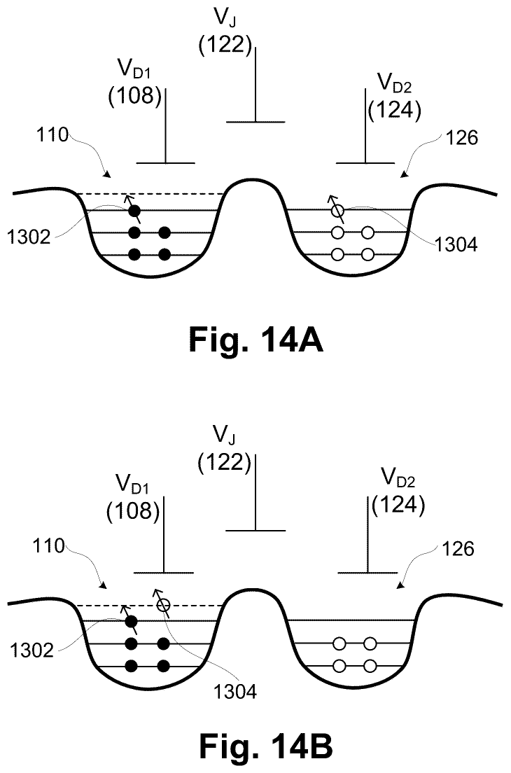

In certain embodiments, a device similar to the device shown in FIG. 1B can be used to perform a two-qubit operation according to aspects of the present disclosure. FIG. 13 illustrates such an example process for performing the two-qubit operation. The method commences at step 1202, where the two multi-electron quantum dots are loaded with electrons to form a monovalent artificial atom in each quantum dot. It will be appreciated that the two quantum dots 110, 126 may have the same number of electrons (e.g., 3, 5, 13, 25, etc.). However, this is not essential. Instead, the quantum dots 110, 126 may have different number of electrons (e.g., quantum dot 110 may have 5 electrons and quantum dot 126 may have 13 electrons) as long as they each have one valence electron in the outermost orbital/shell. FIG. 14A shows a schematic representation of the double quantum dot system 110, 126 where each dot is loaded with five electrons and where the qubit is encoded in the valence electron of each quantum dot.

Next, at step 1204, once the two quantum dots 110, 126 are populated, the detuning between the two quantum dots 110, 126 may be tuned (e.g., by applying an appropriate bias to the gates 108, 122, and 124) to cause the valence electron 1304 in the quantum dot 126 to shuttle to the quantum dot 110 and in particular to shuttle to the outermost orbital of the quantum dot 110. FIG. 14B shows a schematic representation of this, where the qubit 1304 from quantum dot 126 has shuttled to quantum dot 110. This leads to exchange oscillations that are not too fast (varying between negative 100 MHz to positive 100 MHz) and therefore provide good control fidelity.

Thereafter, at step 1206, the shape of the quantum dot 110 in which the two electrons 1302, 1304 are present may be altered to increase the strength of the exchange coupling. This is because the exchange coupling becomes dominated by the energy separation between orbitals. In one example, this may be achieved by applying suitable voltages on the corresponding gates (e.g., gate 108). This alteration of the quantum dot shape affects the strength of the exchange coupling between the two electrons 1302, 1304—i.e., the more elliptical the shape of the quantum dot 110, the higher the exchange coupling strength and the less elliptical the shape of the quantum dot, the lower the exchange coupling strength between the qubits.

The particular range of voltages needed to achieve a certain value of the exchange coupling needs to be calibrated case-by-case, since it is influenced by uncontrollable chemical details of the material stack and the particular circumstances set by all the voltages applied to the gates around the target quantum dot.

Next, at step 1208, the required operation may be performed between the two qubits (e.g., a SWAP operation) and at step 1210, the second qubit 1304 may be shuttled back to the second quantum dot 126 by once again applying suitable voltages to the exchange coupling gate 122.

Accordingly, manipulating the confinement potential of the unpaired electron of a quantum dot can be used to speed up EDSR, enable faster spin relaxations, enable intermediate and long-distance coupling and noise resistant exchange coupling between qubits.

The example spin-based systems and methods described herein utilize electrons. However, it will be appreciated that the systems and methods can just as easily be implemented with holes instead of electrons. In such cases, quantum dots can be formed by binding a controllable number of holes and the ellipticity or confinement potential of an unpaired hole in a quantum dot can be altered by changing the voltages of the arrangement of gate electrodes.

It will also be appreciated that the systems and methods described herein adopts silicon as the semiconductor material for the formation of quantum dots and silicon dioxide as a barrier material, but the invention can be equally implemented in other materials, including silicon-germanium alloys, gallium arsenide, germanium and other combinations of semiconductors and barrier materials.

The methods and the quantum processor architectures described herein uses quantum mechanics to perform computation. The processors, for example, may be used for a range of applications and provide enhanced computation performance, these applications include: encryption and decryption of information, advanced chemistry simulation, optimisation, machine learning, pattern recognition, anomaly detection, financial analysis and validation amongst others.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of controlling a quantum processing element, the quantum processing element comprising:
a semiconductor substrate;
a barrier material formed above the semiconductor substrate such that an interface forms between the semiconductor substrate and the barrier material;
an arrangement of gate electrodes;
an external magnet; and
electronic controllers, the method comprising:
generating an electrostatic confinement potential by applying voltages to the arrangement of gate electrodes for binding a controllable number of electrons or holes, forming a first quantum dot;
applying a constant magnetic field to the quantum processing element using the external magnet, the magnetic field separating energy levels of spin states associated with an unpaired electron or hole of the controllable number of electrons or holes in the first quantum dot; and
changing the voltages of the arrangement of gate electrodes using the electronic controllers to change a shape of a confinement potential of the unpaired electron or hole.

2. The method of claim 1, further comprising modifying the voltages applied to the arrangement of gate electrodes to change the shape of the confinement potential, which alter an excitation spectrum of the first quantum dot to enable fast control of the spin states of the unpaired electron or hole.

3. The method of claim 1, further comprising applying an additional alternating voltage to the arrangement of gate electrodes to electrically drive transitions between the spin states of the unpaired electron or hole.

4. The method of claim 1, further comprising modifying the voltages applied to the arrangement of gate electrodes to change a shape of the first quantum dot wavefunction, which alters an excitation spectrum of the first quantum dot to enable fast relaxation between the spin states of the unpaired electron or hole.

5. The method of claim 1 wherein the quantum processing element further comprises a second quantum dot having a controllable number of electrons or holes, and wherein the method further comprises:
temporarily transferring the unpaired electron or hole from the first quantum dot to the second quantum dot containing an unpaired electron or hole; and
adjusting the voltages applied to the arrangement of gate electrodes to tune a shape of the second quantum dot wavefunction in order to control an exchange energy between the two electrons or holes.

6. The method of the claim 1, further comprising modifying the voltages applied to the arrangement of gate electrodes to change a shape of the first quantum dot wavefunction, resulting in a change of the wavefunction of the unpaired electron or hole dependent on the spin state of the electron or hole.

7. The method of claim 6, wherein the quantum processing element comprises other quantum dots and wherein the change in the shape of the first quantum dot wavefunction causes an electrostatic repulsion to the other quantum dots resulting in a spin-dependent frequency shift of the unpaired electron or hole in a second quantum dot.

8. The method of claim 6, wherein the electric field created by the spin-dependent change in wavefunction of the unpaired electron or hole couples to a resonator, creating or absorbing a photon.

9. The method of claim 6, wherein the quantum processing element is coupled to a second quantum processing element via a resonator, the second quantum processing element comprising a second quantum dot having a controllable number of electrons or holes and an unpaired electron or hole, and wherein the method further comprises coupling the unpaired electron or hole to the resonator by an electric field created by the spin state dependent change in the wavefunction of the unpaired electron or hole, creating or absorbing a photon.

10. The method of claim 9, further comprising modifying the voltages applied to the arrangement of gate electrodes to change the shape of the first quantum dot wavefunction and the second quantum dot wavefunction coupled to the resonator and the photon created by the spin-dependent change in the wavefunction of the unpaired electron or hole of the first quantum dot is absorbed by the unpaired electron or hole of the second quantum dot, changing its spin state.

11. A quantum processing element comprising:
a semiconductor substrate;
a barrier material formed above the semiconductor substrate such that an interface forms between the semiconductor substrate and the barrier material;
an arrangement of gate electrodes configured to generate an electrostatic confinement potential for binding a controllable number of electrons or holes, forming a first quantum dot
an external magnet configured to apply a constant magnetic field to the first quantum dot to separate energy levels of spin states associated with an unpaired electron or hole of the controllable number of electrons or holes in the first quantum dot; and
electronic controllers configured to change voltages applied to the arrangement of gate electrodes to change a shape of a confinement potential of the unpaired electron or hole.

12. The system of claim 11, wherein the voltages applied to the arrangement of gate electrodes are modified to change the shape of the confinement potential, which alters an excitation spectrum of the first quantum dot to enable fast control of the spin states of the unpaired electron or hole.

13. The system of claim 11, wherein an additional alternating voltage is applied to the arrangement of gate electrodes to electrically drive transitions between spin states of the unpaired electron or hole.

14. The system of claim 11, wherein the voltages applied to the arrangement of gate electrodes are modified to change a shape of the first quantum dot wavefunction, which alters an excitation spectrum of the first quantum dot to enable fast relaxation between the spin states of the unpaired electron or hole.

15. The system of claim 11 wherein the quantum processing element further comprises a second quantum dot having a controllable number of electrons or holes and wherein the unpaired electron or hole from the first quantum dot is temporarily transferred to the second quantum containing an unpaired electron or hole and the voltages applied to the arrangement of gate electrodes are adjusted to tune a shape of the second quantum dot wavefunction in order to control an exchange energy between the two electrons or holes.

16. The system of the claim 15, wherein the voltages applied to the arrangement of gate electrodes are modified to change a shape of the first quantum dot wavefunction, resulting in a change of the wavefunction of the unpaired electron or hole dependent on the spin state of the electron or hole.

17. The system of claim 16, wherein the quantum processing element comprises other quantum dots and wherein the change in the shape of the first quantum dot wavefunction causes an electrostatic repulsion to the other quantum dots resulting in a spin-dependent frequency shift of the unpaired electron or hole in a second quantum dot.

18. The system of claim 16, wherein the electric field created by the spin-dependent change in wavefunction of the unpaired electron or hole couples to a resonator, creating or absorbing a photon.

19. The system of claim 16, wherein the quantum processing element is coupled to a second quantum processing element via a resonator, the second quantum processing element comprising a second quantum dot having a controllable number of electrons or holes and an unpaired electron or hole, and wherein an electric field created by the spin state dependent change in the wavefunction of the unpaired electron or hole couples to the resonator, creating or absorbing a photon.

20. The system of claim 19, wherein the voltages applied to the arrangement of gate electrodes are modified to change the shape of the first quantum dot wavefunction and the second quantum dot wavefunction coupled to the resonator and the photon created by the spin-dependent change in the wavefunction of the unpaired electron or hole of the first quantum dot is absorbed by the unpaired electron or hole of the second quantum dot, changing its spin state.
